(19) United States
(12) Patent Application Publication
(10) Pub. No.: US 2024/0152175 A1
(43) Pub. Date: May 9, 2024

(54) MANAGING ENERGY IN COMPUTATION WITH REVERSIBLE CIRCUITS

(71) Applicant: ZETTAFLOPS LLC, Albuquerque, NM (US)

(72) Inventor: Erik DeBenedictis, Albuquerque, NM (US)

(21) Appl. No.: 18/282,035

(22) PCT Filed: Mar. 11, 2022
(86) PCT No.: PCT/US2022/019994

§ 371 Date: Sep. 14, 2023

Related U.S. Application Data
(60) Provisional application No. 63/200,548, filed on Mar. 14, 2021.
(60) Provisional application No. 63/200,814, filed on Mar. 30, 2021.
(60) Provisional application No. 63/256,997, filed on Oct. 18, 2021.

(51) Int. Cl. G06F 1/10; G06N 10/20

(52) U.S. Cl. CPC G06F 1/10; G06N 10/20

(57) ABSTRACT

Adiabatic and reversible logic have a previously unexploited ability to manage the location where energy is turned into heat. In addition to reducing the total amount of energy used, this ability can be used to move waste energy away from sensitive components before it is turned into heat, allowing supercomputers and quantum computers to scale to larger sizes. Embodiments herein include an adiabatic powertrain and a new adiabatic logic family called Quiet 2-Level Adiabatic Logic (Q2LAL) that supports energy management both at room (supercomputer) and cryogenic (quantum computer) temperatures. Managing energy effectively requires coordinated actions by a computer's physical and algorithmic components. These embodiments describe how computational tasks can be distributed such that tasks that consume energy and dissipate heat are performed at the most appropriate location without unnecessarily impacting performance. Using the methods herein, a quantum computer design approach is disclosed, which is more suitable to scale up.

### CROSS REFERENCE TO RELATED PATENT APPLICATIONS

This patent application claims the priority and benefit, under 35 U.S.C. § 119(e), of U.S. Provisional Patent Application Ser. No. 63/200,548, filed Mar. 14, 2021, and titled “ENERGY MANAGEMENT WITH ADIABATIC CIRCUITS.” U.S. Provisional Application Ser. No. 63/200,548 is incorporated herein by reference in its entirety.

This patent application also claims the priority and benefit, under 35 U.S.C. § 119(e), of U.S. Provisional Patent Application Ser. No. 63/200,814, filed Mar. 30, 2021, and titled “ENERGY MANAGEMENT FOR ADIABATIC CIRCUITS.” U.S. Provisional Application Ser. No. 63/200,814 is incorporated herein by reference in its entirety.

This patent application also claims the priority and benefit, under 35 U.S.C. § 119(e), of U.S. Provisional Patent Application Ser. No. 63/256,997, filed Oct. 18, 2021, and titled “REVERSIBLE LOGIC FOR CLASSICAL CONTROL OF QUANTUM COMPUTERS.” U.S. Provisional Application Ser. No. 63/256,997 is incorporated herein by reference in its entirety.

### TECHNICAL FIELD

Embodiments are related to the field of electronics. Embodiments are also related to the field of computing systems, including supercomputing and quantum computing systems. Embodiments are further related to the field of cryogenic electronics. Embodiments are further related to classical control systems for quantum computers.

### BACKGROUND

Quantum computer scale up is a current challenge. Not too long ago, the leading quantum computers required each cryogenically cooled qubit to be connected by a cable to room temperature lab equipment. The size of the cable bundle grew and became a scale up limit. More recently classical control systems have been proposed that include electronics collocated with the qubits in the cryostat. The purpose of the control electronics is to decompress data in the cable bundle so it can serve more qubits. However, the dissipation of the electronics located in the cryostat becomes another scale up limit. Thus, there is a need for cryogenic electronics with lower dissipation.

High speed supercomputers face the closely related challenge of packing a lot of computing into a small volume so signals crossing the region do not slow the calculation. This makes lowering dissipation at the site of the computation a priority even if total dissipation remains the same or increases.

There is a theoretical basis for lowering dissipation. In the 1960s, Landauer developed a theory claiming “a minimal heat generation . . . typically of the order of kT for each irreversible function,” where k is Boltzmann's constant and T is the absolute temperature. While Landauer's minimum is valid, it is more than 1,000× below the practical minimum for CMOS of E_{CMOS}=½ CₘᵢₙVₜₕ², where Cₘᵢₙ is the circuit node capacitance and Vₜₕ is the transistor threshold voltage, where both Cₘᵢₙ and Vₜₕ are the minimums over available semiconductor processes. There is also reversible logic theory where E_{reversible}=2RCIτ×½ CV². The expression has been deliberately written as the E_{CMOS} term ½ CV² multiplied by an “energy factor” 2RCIτ for the reversible transistor circuit, where R is the effective “on” resistance of a transistor, C is the capacitance of a signal node, including several transistor gates and wiring capacitance, and τ is the length of a ramp in the power-clock waveform.

Note that Landauer's minimum assumes a system at a single temperature T while cryogenic quantum computers are distributed between a cryostat and room temperature. It is not clear how to apply Landauer's kT minimum to a system with multiple Ts.

There is also an opportunity related to different clock rates between classical and quantum computers. CMOS gate delays have stabilized around 0.1 ns, resulting in 1.5-5 GHz microprocessor clock rates. The speed of recent quantum computers is limited by the quantum measurement operation to about 1 μs, or around 10,000 CMOS gate delays. Since 2RC is essentially the CMOS gate delay and r is the clock period of the reversible logic, a rough order of magnitude for 2RCIτ is 1/1,000. This is a big enough factor to enable scale up for multiple generations.

### SUMMARY

The following summary is provided to facilitate an understanding of some of the innovative features unique to the embodiments disclosed and is not intended to be a full description. A full appreciation of the various aspects of the embodiments can be gained by taking the entire specification, claims, drawings, and abstract as a whole.

It is, therefore, one aspect of the disclosed embodiments to provide a method, system, and apparatus for adiabatic and reversible logic.

It is an aspect of the disclosed embodiments to provide methods and systems for computing.

It is an aspect of the disclosed embodiments to provide methods and systems for supercomputing applications.

It is an aspect of the disclosed embodiments to provide methods and systems for quantum computing applications.

It is an aspect of the disclosed embodiments to provide methods and systems for energy management.

It is an aspect of the disclosed embodiments to provide methods and systems for quantum computer scale up.

Embodiments disclosed herein show how to implement the cryogenic portion of a quantum computer's classical control system in a way that benefits from the energy efficiency of reversible logic, thus enabling further quantum computer scale up.

A cryo-adiabatic powertrain is disclosed that address prior art deficiencies associated with energy-recycling power supplies. The energy efficiency advance is illustrated by Spice circuit simulations in chart 100 of FIG. 1 showing cumulative energy flow into chips as CMOS curve 101 and reversible curve 102. The reversible curve 102 clearly rises more slowly overall, but the shapes of the curves reveal some reasons for the energy efficiency difference.

Since all the energy entering a CMOS chip leaves as heat, CMOS curve 101 rises monotonically. Both circuits drive a signal of amplitude V=10 V to a node with capacitance C=100 pF, which causes the cumulative energy of CMOS curve 101 to make upward steps of CV²=10⁻⁸ J on each 0 to 1 transition.

The key distinction is that a reversible circuit uses energy for a while and then transfers most of it back to the power supply, dissipating only a second order fraction in the cryostat. Thus, the reversible curve 102 makes upward steps on each 0 to 1 transition followed by downward step as the signal goes back from 1 to 0. The steps in reversible curve 102 are about ½ CV², or about half the size of the steps in CMOS curve 101, which are CV². The reason for the 2× difference in step size is due to different charging circuits and will be explained later.

Without the powertrain disclosed herein, reversible logic systems would consolidate energy that has served its purpose into a form that can be recycled. Yet, a high efficiency energy recycling power supply has not been found. The adiabatic powertrain in this disclosure nonetheless reduces dissipation at the site of the computation. The cryogenic extension, the cryo-adiabatic powertrain, additionally reduces refrigeration overhead, which is typically a larger reduction.

The circuit simulated in FIG. 1 shown by reversible curve 102 includes the behavior-controlling portion of the classical control system that is the subject of this disclosure, so the explanation above extends to the scale up of an overall quantum computer.

Using the Prime-Line/Address-Line (PL/AL) architecture as a starting point, the embodiments disclosed herein include a method for creating a reversible logic implementation of the cryogenic processor 3303. Like any (classical) logic implementation, application-specific designs are the most efficient, so the method uses a quantum error correction algorithm as example, transforming the example algorithm into the schematic diagram of a transistor-level implementation.

This part of the method exploits the equation E_{reversible}=2RCIτ×½ CV² mentioned previously. A microprocessor built with reversible logic should, according to the equation, have 1,000× higher energy efficiency than CMOS if operated as 1/1,000 the clock rate, e. g. 1 MHz instead of 1 GHz. Such a microprocessor would be handicapped by low throughput. However, important classes of qubits cannot run faster than about 1 MHz, so a properly designed classical control system with a 1 MHz clock may be fast enough to fully realize the advantages of quantum computing.

The disclosed embodiments further illustrate how to partition the classical control system between the cryostat and room temperature. Formal logic gates, such as AND, OR, NOT, and Toffoli, are complex to implement with reversible logic and become a candidate to placement in the room temperature environment. However, reversible circuits for shift registers, starting and stopping clocks, and busses become candidates for placement in the cryostat.

At the architectural level, a method for generating a schematic for a quantum algorithm based on reversible shift registers is provided. The architecture also includes a novel state machine that is uniquely adapted to a multi-temperature environment.

The embodiments further include architectural enhancements that allow low-dissipation reversible logic to be used in conjunction with a small amount of a faster technology to allow both low dissipation and high speed in the same system.

Shor's quantum factoring algorithm can factor a number in fewer steps than a conventional computer. The disclosed embodiments devise a classical reversible circuit, which is an algorithm at the circuit level, for controlling the quantum computer with less dissipation than cryo CMOS. This allows a quantum computer to run algorithms with both fewer steps and less dissipation, specifically dissipation in the cryostat.

In an embodiment, a method for controlling a quantum computer comprises: moving energy from a power-clock supply to a cryostat, moving a portion of the energy through at least one switch in the cryostat, moving a portion of the energy to control of at least one analog switch in the cryostat, in order to open or close the switch, transmitting a qubit control waveform through the at least one analog switch set to closed, altering at least one qubit, moving a portion of the energy through the at least one switch that was previously set to open or closed, and moving a portion of the energy to the power-clock supply.

In an embodiment, the method further comprises measuring at least one of the qubits, analyzing the result of the measurement using a standard computer, yielding a decision, and setting at least one of the switches with the decision. In an embodiment, setting at least one of the switches comprises scheduling the setting of multiple of the at least one switches. In an embodiment, the method further comprises identifying at least one subcircuit and encoding each of the at least one subcircuits into an AL-bus word. In an embodiment, the method further comprises setting the at least one switch to the AL-bus words. In an embodiment, the method further comprises setting one switch to cause setting all the at least one analog switches to one of the AL-bus words.

In another embodiment, a method for creating a quantum computer comprises identifying a set of prime-line waveforms, turning a quantum algorithm into a subcircuit graph comprised of subcircuits of quantum operation building blocks, parameterized quantum gate operations, and decision elements, substituting a schematic diagram symbol of a bus-enabled storage unit for each subcircuit and a symbol for a parameterized quantum gate operation, connecting outputs to an address-line bus, wiring each subcircuit according to a pattern in the subcircuit graph, simulating the quantum algorithm on a classical computer based on real time measurement results, and sending decision values to a decision element in real time.

In an embodiment each of prime-line waveforms contain a time sequence of quantum operation building blocks. In an embodiment, the method further comprises fabricating a chip from the schematic diagram. In an embodiment, the method further comprises selecting prime-line waveforms from the set of prime-line waveforms to create building blocks that can be applied to a second algorithm. In an embodiment, the method further comprises executing either the quantum algorithm or the second algorithm based on decisions transmitted from the classical computer. In an embodiment, the method further comprises selecting prime-line waveforms to create building blocks that can be applied to the second algorithm. In an embodiment, the method further comprises specifying contents to be loaded into the bus-enabled storage units that can execute either the quantum algorithm, or the second algorithm. In an embodiment, the schematic diagram symbol of a bus-enabled shift register is a reversible shift register.

In another embodiment, a computing system comprises a reversible shift register, at least one power-clock generator creating a power-clock waveform, and a cable bundle between the at least one power-clock generator and the reversible shift register.

In an embodiment of the system, a waveform is predistorted to an inverse of distortion introduced by the cable bundle. In an embodiment of the system, the computing system comprises a multi-temperature hybrid computing system. In an embodiment the system further comprises a cryostat, wherein the reversible shift register is in the cryostat. In an embodiment, the system further comprises a bus interface circuit in the cryostat. In an embodiment the system further comprises an analog signal generator controlled by information from the shift register and a qubit in the cryostat.

### BRIEF DESCRIPTION OF THE DRAWINGS

The accompanying figures, in which like reference numerals refer to identical or functionally-similar elements throughout the separate views and which are incorporated in and form a part of the specification, further illustrate the embodiments and, together with the detailed description, serve to explain the embodiments disclosed herein.

FIG. 1 depicts a summary of the energy efficiency advance, associated with the disclosed embodiments;

FIG. 2 depicts quantum error correction methods as the behavioral specification of a classical control system, associated with the disclosed embodiments;

FIG. 3 depicts multiple simultaneous behaviors in a quantum computer, in accordance with the disclosed embodiments;

FIG. 4 depicts the Prime-Line/Address-Line architecture (PL/AL architecture), in accordance with the disclosed embodiments;

FIG. 5 depicts Prime-Line waveform design criteria, in accordance with the disclosed embodiments;

FIG. 6 depicts the joule-to-joule transfer principle, in accordance with the disclosed embodiments;

FIG. 7 depicts a cryo-adiabatic powertrain, in accordance with the disclosed embodiments;

FIG. 7B depicts a method of optimizing power flows, in accordance with the disclosed embodiments;

FIG. 8 depicts generation of the address-line bus, in accordance with the disclosed embodiments;

FIG. 9 depicts circuit modifications for a bus interface, in accordance with the disclosed embodiments;

FIG. 10 depicts eight-phase reversible logic waveforms, in accordance with the disclosed embodiments;

FIG. 11 depicts a dual-rail data representation, in accordance with the disclosed embodiments;

FIG. 12 depicts transistor subcircuits, in accordance with the disclosed embodiments;

FIG. 13 depicts transistor subcircuits, in accordance with the disclosed embodiments;

FIG. 14 depicts a data-controlled clock timing diagram with a time shift for busses and an additional clamp circuit, in accordance with the disclosed embodiments;

FIG. 15 depicts a data-controlled clock enhanced with ω\hat{x} and w\check{x} for bus control, in accordance with the disclosed embodiments;

FIG. 16 depicts a reversible circuit for an irreversible state machine branching for corrections, in accordance with the disclosed embodiments;

FIG. 17 depicts a DRAM-type external signals and state machine branching for corrections, in accordance with the disclosed embodiments;

FIG. 18 depicts steps associated with a method where a standard computer sends data to a cryogenic reversible processor, in accordance with the disclosed embodiments;

FIG. 19 depicts steps associated with a method to change a quantum algorithm into a control system for the algorithm, in accordance with the disclosed embodiments;

FIG. 20 depicts steps associated with a method of creating the effect of an energy-efficient computer in a cryostat, in accordance with the disclosed embodiments;

FIG. 21 depicts a hardware related startup, in accordance with the disclosed embodiments;

FIG. 22 depicts steps associated with two helper methods for reset, in accordance with the disclosed embodiments;

FIG. 23 depicts steps associated with a reset method, in accordance with the disclosed embodiments;

FIG. 24 depicts waveforms corresponding with FIG. 1, in accordance with the disclosed embodiments;

FIG. 25 depicts alternative architecture with reconfigurable digital and analog functions, in accordance with the disclosed embodiments;

FIG. 26 depicts architecture to improve reaction time, in accordance with the disclosed embodiments;

FIG. 27 depicts circuits for additional Q2LAL gates, in accordance with the disclosed embodiments;

FIG. 28 depicts data communications between domains, in accordance with the disclosed embodiments;

FIG. 29 depicts noise analysis applied to remotely located power-clocks, in accordance with the disclosed embodiments;

FIG. 30 depicts Q2LAL power supply noise including both amplitude and frequency, in accordance with the disclosed embodiments;

FIG. 31 depicts driving a ramped clock through a transmission line, including predistortion, in accordance with the disclosed embodiments;

FIG. 32 depicts the combining of abstractions, in accordance with the disclosed embodiments;

FIG. 33 depicts a block diagram of a quantum computer system which is implemented in accordance with the disclosed embodiments;

FIG. 34 depicts a graphical representation of a network of data-processing devices in which aspects of the present embodiments may be implemented; and

FIG. 35 depicts a computer software system for directing the operation of the data-processing system, in accordance with an embodiment.

### DETAILED DESCRIPTION

The particular values and configurations discussed in the following non-limiting examples can be varied, and are cited merely to illustrate one or more embodiments and are not intended to limit the scope thereof.

Example embodiments will now be described more fully hereinafter with reference to the accompanying drawings, in which illustrative embodiments are shown. The embodiments disclosed herein can be embodied in many different forms and should not be construed as limited to the embodiments set forth herein; rather, these embodiments are provided so that this disclosure will be thorough and complete, and will fully convey the scope of the embodiments to those skilled in the art. Like numbers refer to like elements throughout.

The terminology used herein is for the purpose of describing particular embodiments only and is not intended to be limiting. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Throughout the specification and claims, terms may have nuanced meanings suggested or implied in context beyond an explicitly stated meaning. Likewise, the phrase “in one embodiment” as used herein does not necessarily refer to the same embodiment and the phrase “in another embodiment” as used herein does not necessarily refer to a different embodiment. It is intended, for example, that claimed subject matter include combinations of example embodiments in whole or in part.

In general, terminology may be understood at least in part from usage in context. For example, terms, such as “and,” “or,” or “and/or,” as used herein may include a variety of meanings that may depend at least in part upon the context in which such terms are used. Typically, “or” if used to associate a list, such as A, B or C, is intended to mean A, B, and C, here used in the inclusive sense, as well as A, B or C, here used in the exclusive sense. In addition, the term “one or more” as used herein, depending at least in part upon context, may be used to describe any feature, structure, or characteristic in a singular sense or may be used to describe combinations of features, structures or characteristics in a plural sense. In addition, the term “based on” may be understood as not necessarily intended to convey an exclusive set of factors and may, instead, allow for existence of additional factors not necessarily expressly described, again, depending at least in part on context.

Unless otherwise defined, all terms (including technical and scientific terms) used herein have the same meaning as commonly understood by one of ordinary skill in the art. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

While today's small-scale quantum computers are programmed via sequences of gate operations chosen from a universal quantum gate set, future large-scale quantum computers will use quantum error correction. Quantum error correction imposes additional structure on quantum computers that will be exploited in this disclosure.

While qubits 3305 and quantum gates will remain as low-level primitives, error-corrected qubits and operations on them will emerge as new higher-level primitives. This is like classical computers grouping bits into integers and floating point data types and then performing arithmetic operations on the new data types, creating a module 3502.

Controller Behavior

Embodiments herein disclose a method of translating a quantum algorithm into a reversible transistor circuit that will direct qubits through the proper sequence of gate operations. The first step is to subdivide the overall sequence into subcircuits and characterize the way they are assembled. The result is called a subcircuit graph.

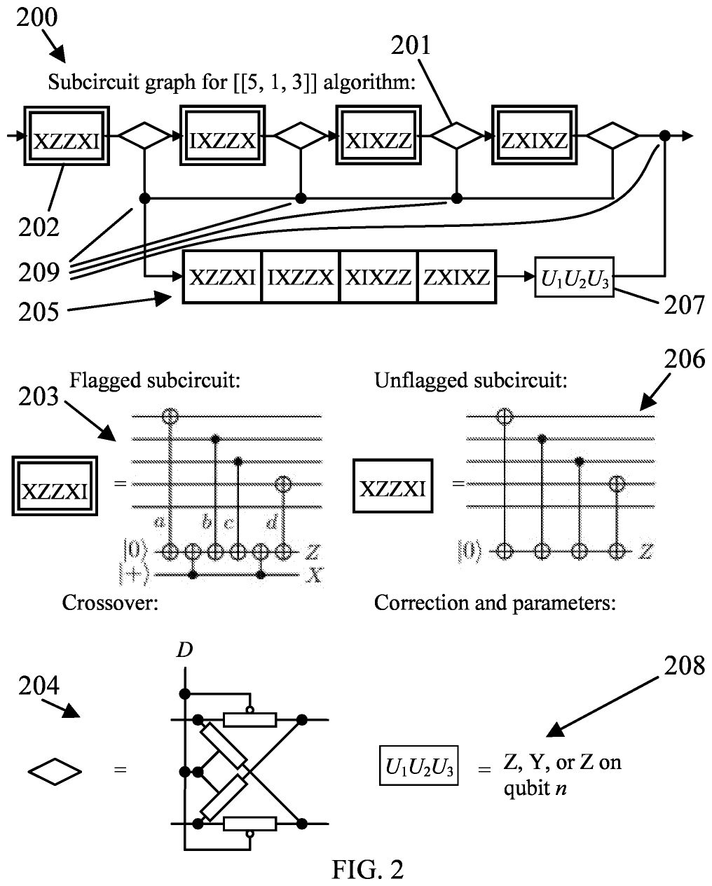

FIG. 2 illustrates a subcircuit graph 200 for detecting and correcting errors in a 5-bit error-corrected qubit, or logical qubit, designated. The subcircuit graph 200 is composed of boxes, such as double-outlined subcircuit 202, diamonds 201, and corrections 207.

In rough equivalence to a 5-bit byte in a classical computer, a quantum computer supporting the code would perform operations on groups of 5 qubits at once. A textual representation of a quantum algorithm associated with this method appears below, corresponding to the first row in the subcircuit graph 200:
if (S_{XZZXI}) fix_error
else if (S_{IXZZX}) fix_error
else if (S_{XIXZZ}) fix_error
else if (S_{ZXIXZ}) fix_error, (code_1)

where S_{XZZXI} performs verification or a syndrome check corresponding to the pattern XZZXI, returning true if there is an error. The three other patterns like XZZXI are circular rotations of the symbols.

Other algorithms require various forms of a looping construct, which would have the textual representation:
while (M_{continue}) iteration, (code_2)

where iteration performs a quantum operation that may work correctly or incorrectly, or may compute an increasingly accurate value as it is executed repeatedly. M_{continue} can be a test for the correct answer, or an answer that has converged to a sufficiently accurate value.

Single- and double-outlined boxes represent subcircuits. For illustration, double-outlined subcircuit 202 verifies the integrity of the XZZXI syndrome using flags that also detect errors in the gates that perform the verification. The symbols “XZZXI” in flagged subcircuit 203 represent the connection pattern and gate type between the five data qubits (top five horizontal lines) and the computational or ancilla qubits (two horizontal lines at the bottom of flagged subcircuit 203).

Subcircuits in an error-corrected quantum computer will have a characteristic structure comprising state preparation, quantum gates with a connection pattern, ending in quantum measurements. This structure is visible in flagged subcircuit 203 as:
state preparation: the “ket” notation |0> and |+>at the left terminus of some of the horizontal lines representing a qubit's timeline
quantum gates: vertical lines with dots or other symbols where they intersect the timeline of several qubits
quantum measurement: letters Z and X at the right terminus of horizontal lines representing a qubit's timeline.

This structure is due to certain properties of error-corrected quantum computation that will be important later in this disclosure and are explained below.

First, errors occur often enough that the probability of an error after even a handful of gates presents too much risk, so long sequences must be avoided. To reduce risk, quantum error correction operations such as code_1 above or the subcircuit graph 200 can be inserted to reset the accumulating error probability before it becomes too large.

However, error correction operations must include qubit measurements, which convert the quantum state into a classical binary value, e.g. 0 or 1, and set the qubit to a known state. This naturally organizes quantum sequences into the preparation-gates-measure structure.

The subcircuit graph makes the conditional branch if (S_{XZZXI}) in the textual representation, which is represented by the crossovers 204 acting on decisions D based on a qubit measurement. If the qubit measurement reports no error, the execution flows to the next line in the textual description, or across the top row of subcircuit graph 200, and verifies the next pattern IXZZX, and so on.

If all four checks succeed, the error check completes having found no errors.

However, if verification reveals an error, the textual construct fix_error is executed and the flow of control moves to the four abutting boxes 205. In the second row, all four check qubits are verified by four abutting boxes 205 representing unflagged subcircuit 206. Unflagged subcircuit 206 contains the same connection pattern as flagged subcircuit 203, but without flags so there is only one ancilla qubit at the bottom.

The information from all the measurements becomes input to an algorithm on the standard computer 404 or computer 3301 that predicts the most likely set of quantum errors responsible for the observed error measurements. This algorithm will specify corrections 207 on up to three qubits, designated Uᵢ, Uⱼ, and Uₖ, where each such parameter 208 is one of the three single-qubit, parameterized gate operations X, Y, or Z, but may also be I, the identify operation, indicating no correction is needed on a particular qubit. Variables i, j, and k identify which qubit receives the correction.

Thus, by varying the decisions controlling crossovers 204 and providing parameters 208, the subcircuit graph will generate all behaviors that algorithm code_1 could apply to the qubits.

It should be recognized that this disclosure is not limited to code_1 or the subcircuit graph 201 but instead describes a method for transforming any algorithm into a classical control system. The subcircuit graph is an intermediate representation like a code tree in a compiler or a netlist in a hardware design. In other aspects it is possible to replace the boxes and diamonds with circuits, reinterpreting the arcs of the graph as wires, thus transforming the subcircuit graph into a schematic diagram of a classical control system that will run the algorithm. The method can also be applied to quantum behavior where the behavior is not an algorithm per se but a series of functional building blocks that could be combined at a higher level to create many quantum algorithms.

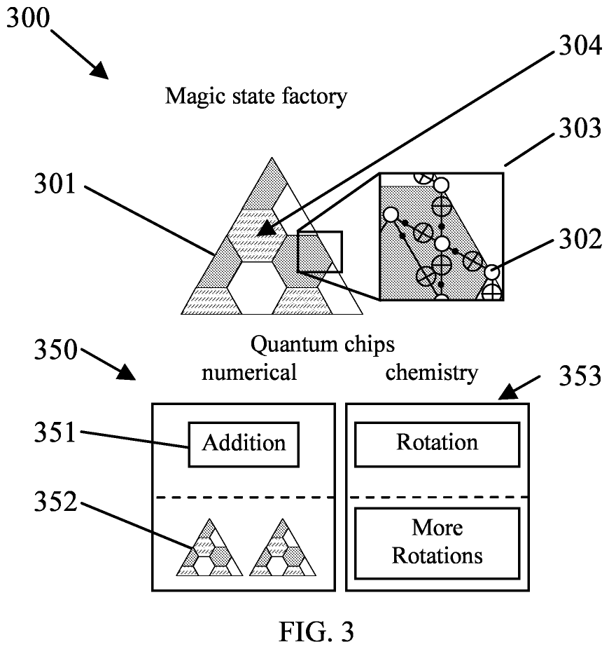

However, the magic state factory 300, illustrated in FIG. 3, shows that a full quantum computer can comprise multiple subcircuit graphs 301 operating simultaneously. It could also represent different behaviors 350 operating on different qubits or at different times.

At a higher-level, a quantum computer could act on qubit subsets 304 independently, such as the qubits on the surface of a chip bounded by a hexagon. Each group could be executing a different subcircuit graph such as addition 351 or magic state 352 preparation. These can be important combinations; for example, addition 351 uses Toffoli gates that are most efficient when provided with special resource states called magic states 352.

Over a longer timeframe, a second user may want to run a chemistry application where the most important low-level operations are rotations 353. The second user may wish to reset the quantum computer and replace the subcircuit graphs for the low-level adder 351 and magic state 352 algorithms with the subcircuit graph for rotations 353.

The discussion above motivates a set of quantum-classical primitives that become input to a method for creating a reversible classical control system for a particular algorithm:
At minimum, a set of universal quantum gates plus measurements. Beyond the minimum, the set may include separate operations for each input of a two-qubit gate (such as “control of a CNOT gate” and “target of a CNOT gate”) and composite operations, such as “Hadamard, one input of control-Z, Hadamard.”
Boxes of functional type containing quantum subcircuits, such as flagged subcircuit 203 and unflagged subcircuit 206, typically ordered as state preparations, one or more gate operations, and ending in qubit measurements.
Boxes of functional type, such as correction 207, containing single-qubit gate operations Uᵢ specified by parameters 208 where the operation type U and qubit identity i are determined by measurements.
Diamonds 201 that decide which of several operations is to be carried out next based on the results of measurements.
A subcircuit graph 200 comprising boxes and diamonds connected by lines or an equivalent textual representation containing if and while statements.
A higher-level structure comprising multiple subcircuit graphs 301, each acting on a subset of the qubits 304, such that qubits may interact with boundary qubits 302 or with qubits in adjacent subsets and change their behavior over time 350.

The Prime-Line/Address-Line (PL/AL) Architecture

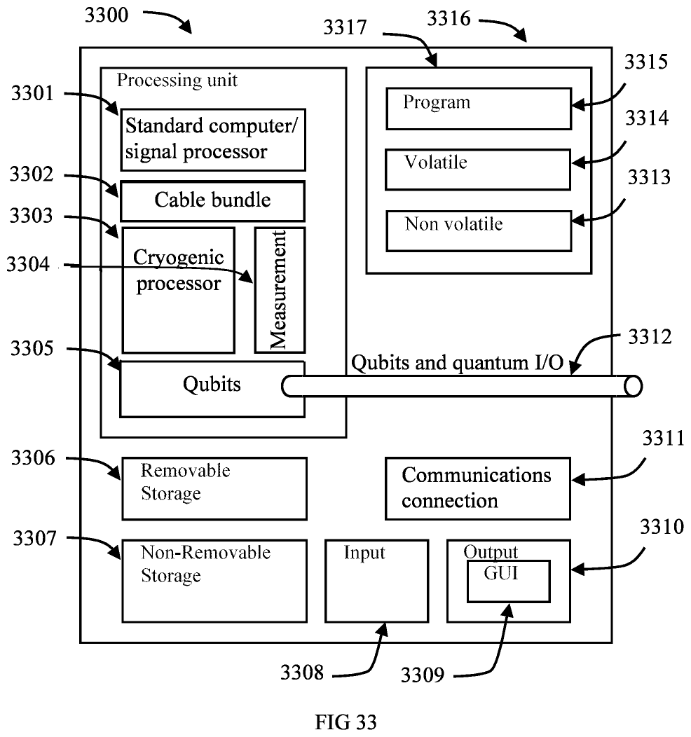

Referring to FIG. 33, a challenge in quantum computer scale up is to replace the potentially unwieldy cabling bundle 3302 crossing from room temperature into the cryostat with a smaller bundle and a more sophisticated cryogenic processor 3303 in the cryostat. Viewed at a high level, the cryogenic processor will function as a data decompressor—a function familiar to most computer users through programs that unzip compressed .zip files on personal computers.

However, data compression formats, and hence the architecture of data compressors and decompressors, are specific to patterns and statistical properties of the data being compressed, which were described previously as subcircuits which will be common in future error-corrected quantum computers.

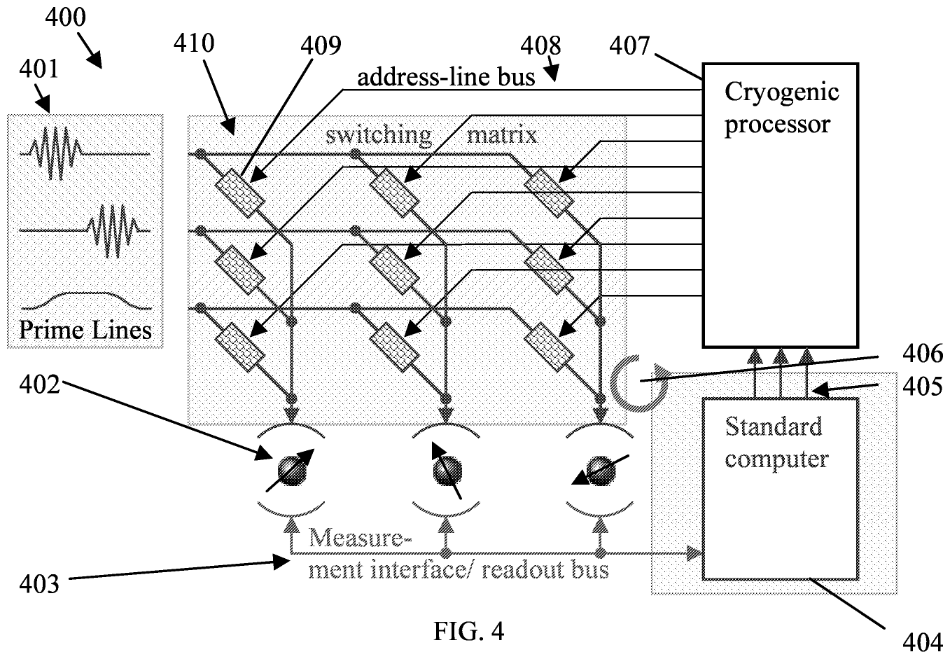

To address this challenge, FIG. 4 illustrates the PL/AL architecture 400 for large-scale quantum computing. In this architecture, operations on n_{q}=3 analog qubits 402, which further detail qubits 3305, occur when one of nₚ=3 analog prime line waveforms 401 defining, at minimum, single- or two-qubit quantum operations, is applied to the qubits 402. The shaded region shows nₚ=3 illustrative prime-line waveforms 401, collectively called a prime-line bus.

A standard computer 404, further detailing computer 3301, computes a digital compressed representation for cable bundle 405 of the waveforms that are to be applied to the qubits, and passes the information to the cryogenic processor 407, which further details processor 3303, for decompression and reformatting of the data into a sequence of up to nₚ×n_{q}—bit AL-bus words to be transmitted on the AL-bus 408 and send to switching matrix 410.

In the PL/AL architecture, each wire of the AL bus 408 from the cryogenic processor 407 connects to the gate of a High Electron Mobility Transistor (HEMT) 409, turning it on or off, and controlling whether one of the prime-line waveforms 401 connected to the HEMT's source or drain is applied to one of the qubits 402 connected to the HEMT's third terminal. The definition of the PL/AL architecture uses a HEMT 409, but standard MOSFET transistors or circuits of transistors or Josephson junctions can perform the same function.

For completeness, it should be clear a cryogenic processor 407 chooses which prime line waveform 401 or gate to apply to each qubit 402 on each time step. Switching matrix 410 makes the actual connection from one waveform 401 to each qubit 402 on each time step, where the waveforms are generated at room temperature. Measurement is performed by exposing qubits 402 to waveforms generated in the standard processor 404 at room temperature and routing the signal through readout subsystem 403, which further details measurement subsystem 3304, and back to room temperature. At room temperature, signal processing apparatus on standard computer 404 processes the reflected signals, passing the digital measurement results to a cryogenic processor 407. As shown by the circular arrow 406, the overall information flow is counterclockwise around the location indicated.

Waveforms on the Prime-Line Bus

The designer has a choice of how to subdivide gate operations, a choice that can have a significant performance impact.

For example, the first and last gates in flagged subcircuit 203 have ⊕ symbols on both ends. This is shorthand notation meaning that one of the ⊕ symbols is to be replaced by the three-gate sequence (1) Hadamard (2) control of a CNOT gate (3) Hadamard. With this replacement, the shorthand becomes a CNOT gate. The designer can choose to consider these as three familiar gates or a single new one, but the qubit must be exposed to the same waveform either way.

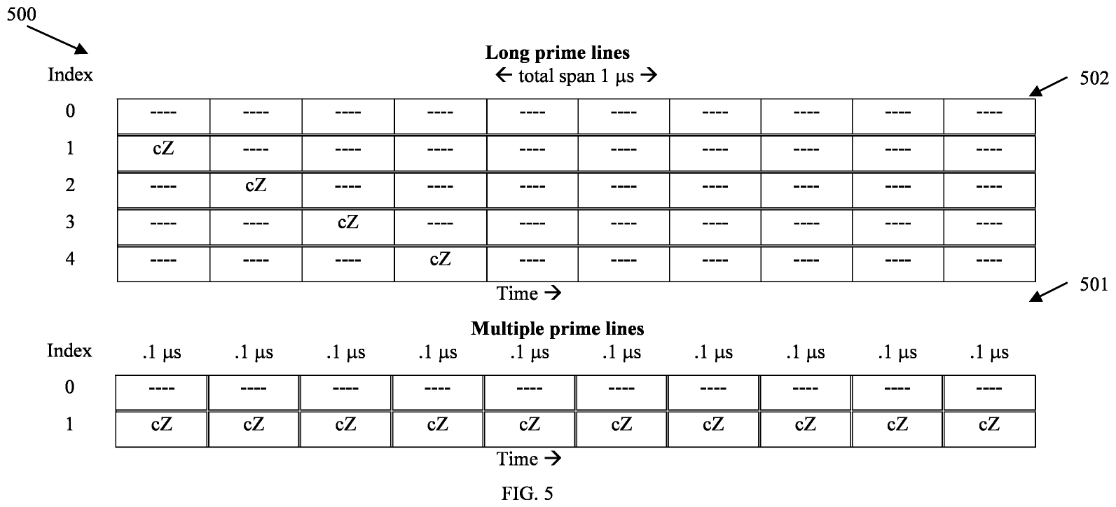

The choice in the paragraph above applies in this disclosure, yet a gate in this disclosure can also have a time offset within the prime-line waveform, as illustrated in chart 500 of FIG. 5. Say prime-line waveforms have period of 1 μs in some design. The designer can imagine the 1 μs to be divided into 10 sub periods as shown in the waveforms 502. Prime-line waveforms indexed 1-4 transmit the same cZ (control-Z) waveform yet with an offset that is 100 ns greater than the previous waveform. Thus, prime-line waveform with index 4 transmits control-Z with a 300 ns offset.

Prime-line waveforms in an alternative design 501 could have a period of 0.1 μs, so prime line waveform with index 1 transmits control-Z every 0.1 μs. To transmit a control-Z offset by 300 ns, the controller would specify three repetitions of prime line index 0, which would do nothing to the qubit for 300 ns, followed by prime-line waveform 1 that transmits control-Z.

The first requires more prime-line waveforms whereas the second requires the controller run 10× faster for 10× as many steps. The energy factor in a reversible logic system is 2RCIτ, so the 10× faster clock in the second case makes τ 10× smaller, so the energy per operation is nominally 10× higher. Since there are also 10× as many operations, the total energy dissipated by the controller would be nominally 100× higher for the same function.

The discussion above illustrates a tradeoff imposed by the physics of computation but potentially mitigated as disclosed herein. Prime line waveforms are selected to be flexible enough to implement the required algorithm, but this leaves design freedom that can be managed to trade controller speed and hence dissipation versus the number of waveforms that require resource-intensive transmission through the cryostat boundary.

CMOS does not offer this tradeoff; it runs fast and at a high power no matter what.

Cryo-Adiabatic Powertrain

For a room temperature adiabatic or reversible transistor circuit to reduce wall-plug energy consumption in practice would require a highly efficient energy-recycling power supply.

Some qubit types require cryogenic operation, so the elusive power supply would have the power source at room temperature but the load in a cryostat. This disclosure creates an alternative to the energy recycling power supply called a cryo-adiabatic powertrain that exploits this special case.

Joule-to-Joule Transfer when Charging a Capacitor

Most computing technologies use voltage-based signaling where dissipation is dominated by the energy required to charge the node capacitance of the wires holding voltage-based signals.

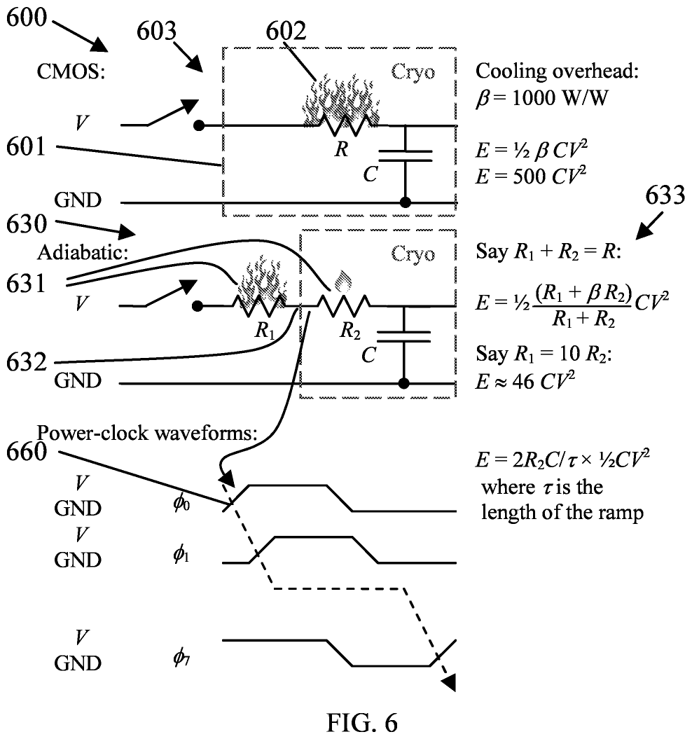

FIG. 6 includes CMOS and adiabatic diagrams 600 that compare the dissipation of two circuits charging a capacitor in a multi-temperature system, extending the comparison to the wall-plug energy consumption.

As illustrated by circuit 603, CMOS switching dissipates ½ CV², where C is the wire or node capacitance and V is the supply voltage. If the CMOS is in a cryostat 601, the circuit's dissipation, indicated by the flame 602, should be multiplied by the refrigerator's energy overhead factor β to obtain wall-plug energy consumption, where β≈1,000 for typical refrigerators cooling to 4 K. Thus, the wall-plug energy consumption will be 500 CV² per transition. The overhead factor β in this document is related to a concept called Specific Power P_{S} by the equation β=P_{S}+1.

However, circuit 630 shows resistance R being split into two series resistances R₁ and R₂, R₁+R₂=R, forming divider 631, where R₁ is outside the cryostat. The total energy drawn from the power supply must be the same because two resistors in series is just another resistor, but only R₂'s dissipation is in the cryostat and contributes to cooling overhead.

The proportion of dissipation in the cryostat will depend on the relative values of R₁ and R₂, but if we take R₁=10 R₂ as an example, the total wall plug energy consumption will be about 46 CV² by calculations 633. That is more than a 10× reduction over the 500 CV² for CMOS.

Many activities performed in a cryostat will inevitably incur a cooling overhead of β ≈1,000 for typical refrigerators cooling to 4 K. However, the task of charging a capacitor can be optimized in this situation so most of the dissipation occurs outside the cryostat.

Ramped Waveforms Leading to a Logic Family

While the circuit 630 is powered from the fixed voltage on the left, voltage enters the cryostat at the center point 632 of divider 631. For a given charging time τ, the smallest dissipation in R₂ occurs when the capacitor is charged at a constant current. This requires R₁ to be a variable resistance that creates a ramped waveform called an AC power-clock 660 at the center point 632 of divider 631.

Charging the capacitor moves charge Q=CV through R₁, R₂, and into C. If the charging is a constant current for time r, the current will be I=CVIτ, and, using the relationship P=I²R, the power dissipation will be C²V²RIτ². This power persists for time τ, dissipating energy E=C²V²RIτ=2RCIτ×½ CV², which is an expression seen frequently herein.

If the voltage entering the cryostat is a fixed waveform, the voltage can be generated once and connected to many instances of R₂ and C in parallel. Such a ramped waveform is called an AC power-clock 660.

In reversible logic, the R₂'s are sometimes modeled by the average Rₒₙ of transistor source-drain channels and the C's are the average capacitance of transistor gates. Energy from a power-clock will pass through one or more transistors in the on state and charge the capacitive gate of another transistor. Current will not pass through a transistor in the off state, thus allowing or preventing gates from being charged based on logic built into the circuit.

AC power-clocks 660 for adiabatic and reversible logic families have upward- and downward-sloping ramps. These logic families can have four to eight overlapping clocks with flat tops and bottoms. The flat tops and bottoms let the overlapping clocks take turns charging capacitors.

It should be noted that Rₒₙ and C of real transistors vary with the gate voltage, so the most energy efficient wave form may be flatter in the middle instead of a perfectly linear ramp.

The multiple overlapping clocks mean the gates set by a power-clock will depend on the whether previous power-clocks left transistors on or off. Furthermore, gates set by a power-clock will influence the results of later power-clocks.

The reversible operation just described is fundamentally different from the way CMOS operates, but both are capable of producing universal logic and memory.

The advantage of reversible logic compared to CMOS is that energy is returned to the room temperature power supply before being turned into heat, as shown by reversible curve 102.

Power Flow Away from Sensitive Circuitry

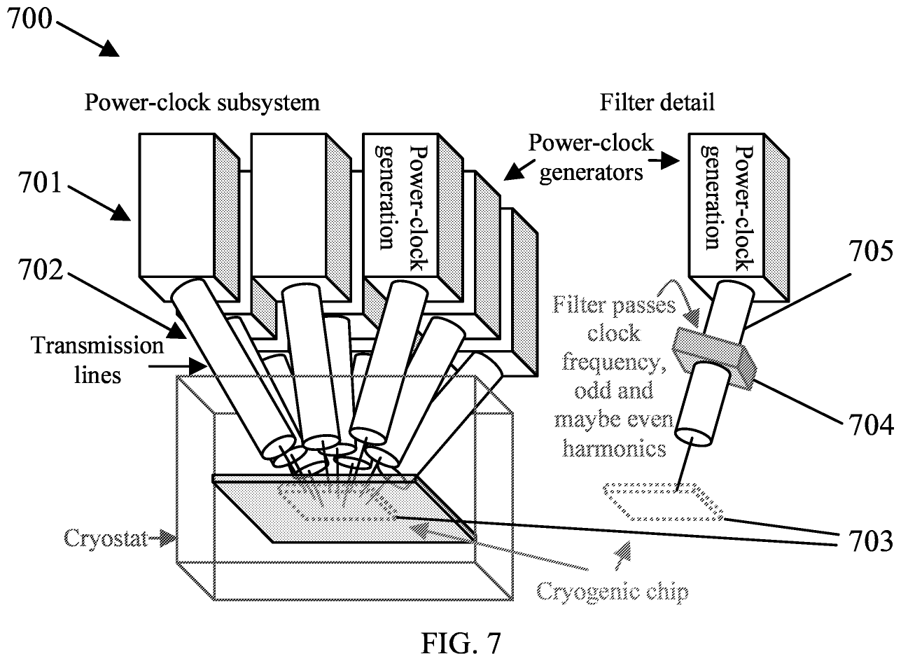

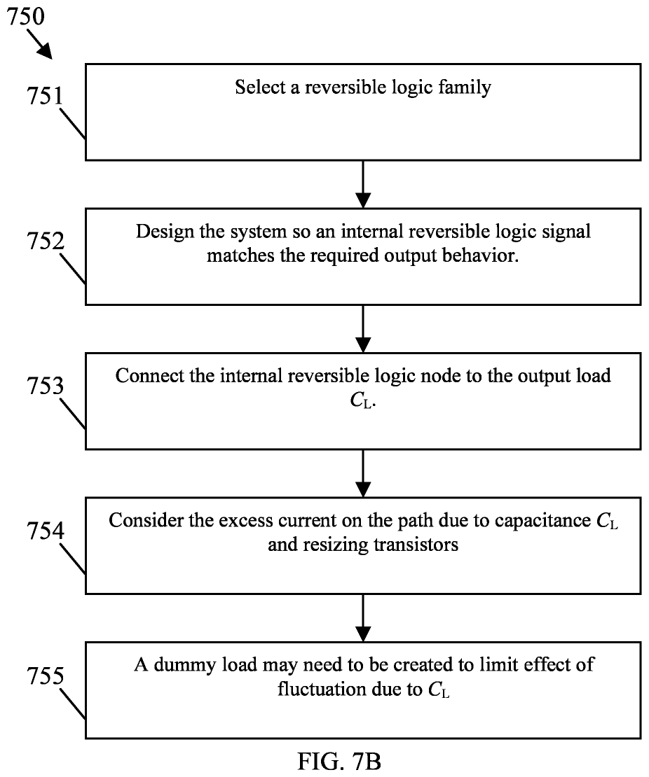

FIG. 7 illustrates the adiabatic powertrain's power-clock generators 701, which are large heat dissipating structures best located outside the cryostat.

In a cryogenic implementation, power-clocks of about 1 MHz will cross the temperature gradient in transmission lines 702, encountering a mismatched termination near the cryogenic chip 703. The transmission lines for typical cryogenic setups can be around a meter long and include filters 704 on the transmission line 705, which reduce noise at frequencies that are not part of the power-clock waveform.

This is similar for a room-temperature adiabatic supercomputer. The difference is that the power-clocks will be around 1 GHz and the supercomputer chip can dissipate more power, up to hundreds of watts, yet the cables do not have to cross a large temperature gradient, so they can be just a few centimeters in length.

Quantum computer control electronics can operate well below qubit control signals of a few GHz, so the transmission line length will be close to a wavelength in either case.

Thus, analysis of the cable between the clock generator and the chip may include transmission line effects due to length, frequency, and crosstalk. Accordingly, power-clock generators 701 may need to launch predistorted waveforms into transmission lines 702 such that they end up as linear ramps when they arrive at the chip.

The end of the transmission line connected to the adiabatic circuit will have a largely capacitive load, leading to reflections. The reflections carry energy out of the cryostat that would otherwise be dissipated.

The effect of the transmission line will depend on the circuit's loading, which in turn depends on the algorithm being performed. Further discussion of these issues will be deferred until later in this disclosure.

Reversible Logic Circuits

Shift registers are the most basic reversible circuits. They are simultaneously single-input non-inverting gates (buffers) and a string of flip flops, making them appropriate circuits for defining adiabatic and reversible logic families, including CRL, SCRL, 2LAL, S2LAL, Q2LAL, RERL, and nRERL.

A circular shift register is an ideal test circuit for measuring or simulating dissipation properties, including all the families listed above. A multi-stage circular shift register contains only one circuit type and naturally multiplies the dissipation by the number of stages. It follows to divide measurements by the number of stages, improving accuracy. Measured results have validated the inverse clock period dependence in the energy expression E=2RCIτ×½ CV².

FIG. 6 circuit 630 showed how to charge a capacitive node with high energy efficiency using a ramped waveform, but the capacitor should be fully discharged before applying the ramp. If not, the initial part of the ramp will abruptly discharge the capacitor, creating a dissipation spike.

In reversible logic, the signal energy in each stage is recovered after the signal moves to the next stage, where it gates a power-clock in the opposite direction. Every stage in a circular shift register has a “next stage,” but a linear shift register “ends” at some point. At this point, the energy is not recoverable.

A minimum dissipation applies only to irreversible functions yet transistor circuits cannot reach the kT minimum. The minimum may be ½ CV², yet a specific circuit node will have specific values of C and V, which can take any values larger than the minimum set by the process used to fabricate a chip. If the values of C and V are larger than this minimum, a signal can be passed through one or more reversible shift register stages with progressively smaller C's and Vs until they reach a stage with C=Cₘᵢₙ and the V=Vₜₕ, where Cₘᵢₙ and Vₜₕ are set by the process used to fabricate the chip. At this point, the unrecoverable signal energy will be ½ Cₘᵢₙ Vₜₕ².

The discussion above illustrates a key design tradeoff in reversible logic. Properly designed reversible logic circuits obey the relationship E=2RCIτ×½ CV², where 2RCIτ is of rough order of magnitude 1/1,000 for a classical control system. Failing to properly reverse a single stage would make circuit 630 inapplicable and cause the circuit to dissipate the entire ½ Cₘᵢₙ Vₜₕ². Thus, it is preferable to recover energy if it can be done with fewer than about 1,000 gates, otherwise the dissipation of the recovery circuit will be larger than the amount of energy recovered.

A Reversible Shift Register can Drive the Switch Matrix Directly

The task of creating a reversible logic circuit for decompressing quantum gate sequences is possible. A first step is to consider the straightforward playback of a stored gate sequence.

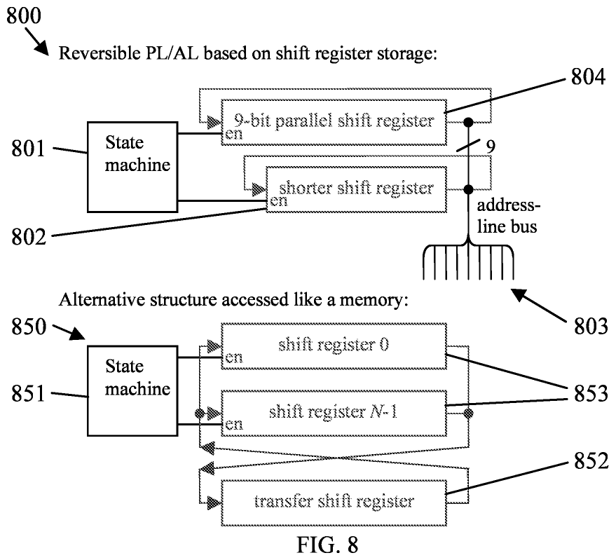

Referring to FIG. 8, the system 800 includes shift register 802 as an example. A representation of unflagged subcircuit 206 is stored in shift register 802. Its output comprises AL-bus words that drive AL-bus 803, shown as 9-bits wide in AL-bus 408. Data on AL-bus 803 turns analog waveforms on and off.

As stated above, the PL/AL architecture can use a matrix of High Electron Mobility Transistors (HEMTs) 409 as switches. An HEMT is controlled by a 300 mV signal, which is about the same as the operating voltage V used for the circuits disclosed herein. So, the output of the shift register could be connected to the gate of an HEMT.

Circuit 630 will see the HEMT's gate capacitance C_{L} in parallel with the circuit's electrical node capacitance C and will naturally dissipate most of the ½ (C+C_{L})V² energy outside the cryostat. In fact, the large jumps up and down in reversible curve 102 are ½ (C+C_{L})V².

If the HEMT presents a large capacitance C_{L}—such as a large HEMT or a remotely located HEMT with a lot of interconnect capacitance—the large load may cause I²R power dissipation in the transistors creating the signal. This dissipation will be quadratic in C+C_{L} and may be too large. The remedy is to increase the transistor widths on either side of the bus. Thus, the transistors are 4× wider on the path between the power-clock and the address-line bus in circuit generating reversible curve 102.

In conventional logic design, the logic is not altered for the benefit of I/O devices. Instead, an output buffer is created to convert the logic signal into the required output form. In the disclosed embodiments, the adiabatic logic is allowed to pass both data and energy recycling capability to output devices.

Design Process for Recovering Energy from Reversible Logic Output Signals

The method 750 for recycling energy on circuit outputs with capacitive load C_{L} is illustrated in FIG. 7B.

In step 751, a reversible logic family with suitably shaped statically driven signal waveforms is selected, modifying the family if necessary. For example, the family used for illustration in this example has 2-level signals that are stable for 5 out of 8 clock ramp periods, and all circuit nodes are statically driven.

In step 752, the system can be designed so an internal reversible logic signal matches the required output behavior. For example, the active portion of prime-line waveforms 401 must fit within the 5 out of 8 ramp periods where the reversible logic signal is stable to function correctly. Furthermore, the power-clock 660 is generated by a room-temperature waveform generator that must tailor the wave period and shape to both correct for distortions or other imperfections in transmission to the cryostat and match requirements for the output signal. For example, the power-clock 660 may have requirements in terms of frequency, jitter, and noise that are more stringent than necessary for just reversible logic. Further discussion of clock-power wave period and shape is further detailed herein.

In step 753, the internal reversible logic node is connected to the output load C_{L}.

In step 754, the excess current on the circuit path between the power-clocks and the output due to capacitance C_{L} can be considered, and the transistors along this path are resized accordingly.

In step 755, a dummy load may need to be created. For example, if there is a C_{L} on the A branch of node 3104, a dummy C_{L} may be needed on the —A branch to assure the cryogenic chip 703 places a constant load on the transmission line 702. Further discussion of capacitance matching is deferred to later in this disclosure.

Clock Enables and Busses

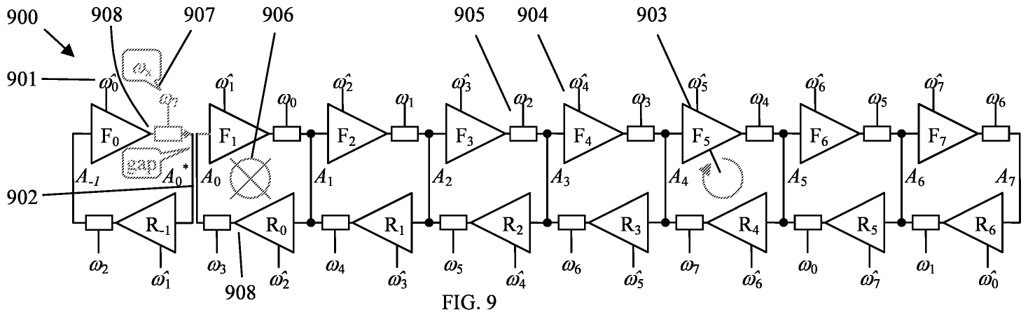

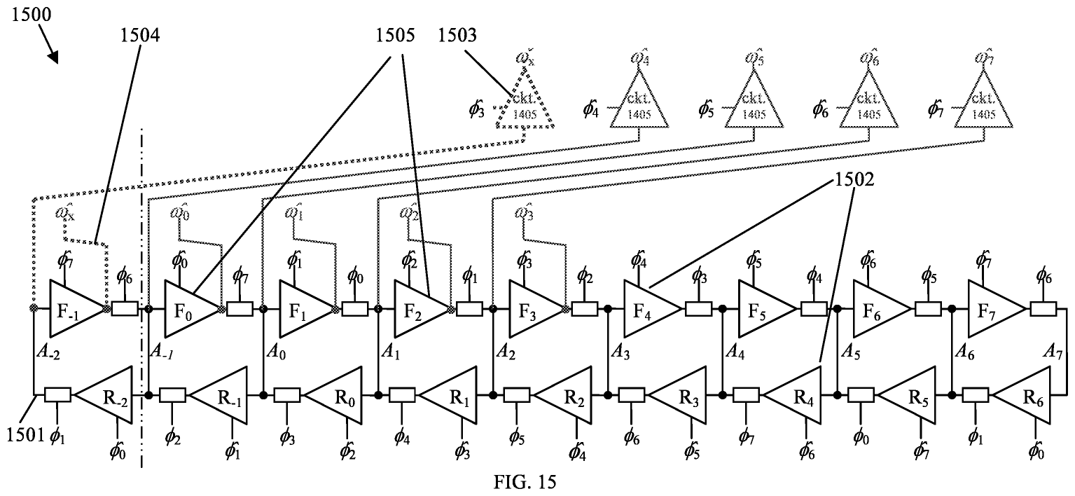

The reversible system 800 cosmetically appears to be a reversible classical control system, but there is no reversible prior art for either clock enables or bus interfaces. FIG. 9 discloses a shift register with an enable and a bus interface and FIG. 15 discloses a compatible data-controlled clock that supports bus signals.

FIG. 9 illustrates a circuit 900 which enhances a reversible shift register so it can be disabled, not just stopping it from shifting, but by disabling it from driving one of its data wires when disabled. The circuit 900 will be explained after disclosing prerequisite components.

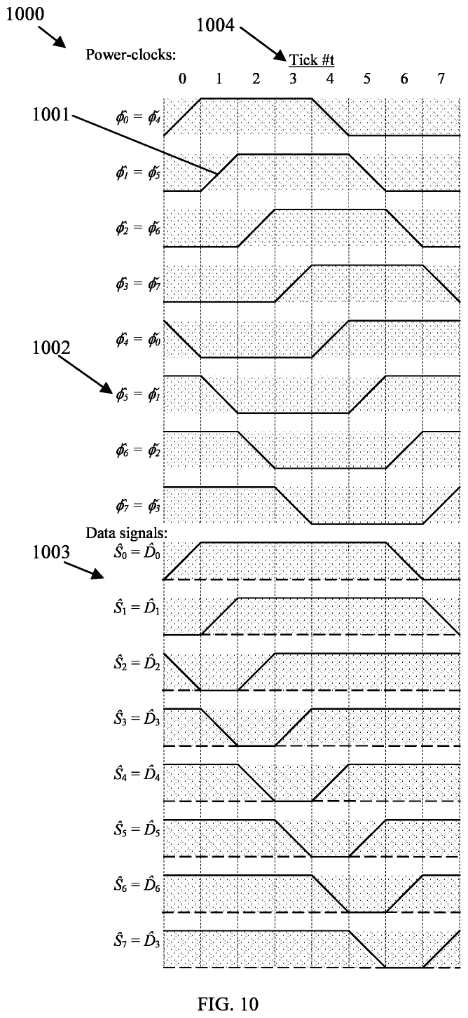

FIG. 10 shows a chart 1000 of waveforms in the exemplary 8-phase reversible logic family called Quiet 2-Level Adiabatic Logic (Q2LAL). The power-clocks 1002 are divided into ticks 1004 of duration 1; the ramp time. The power-clocks can be labeled \hat{ϕ}₀₋₇, where the circumflex (hat) accent indicates that the power-clock is a positive-going pulse. However, flipping a power-clock upside down yields the same waveform as a pulse four ticks ahead or behind. Thus, the power-clocks have the property that \hat{ϕ}ᵢ=\check{ϕ}_{i+4 mod 8}, where the caron (cup) accent indicates the clock is a negative-going pulse.

Data signals 1003 follow a reversible electrical protocol. The signal starts at a resting or reset state of 0 V for one tick of duration τ. If the signal is to be V volts, it rises in one tick of duration τ, stays at V for five ticks and then ramps back to GND in the sixth tick.

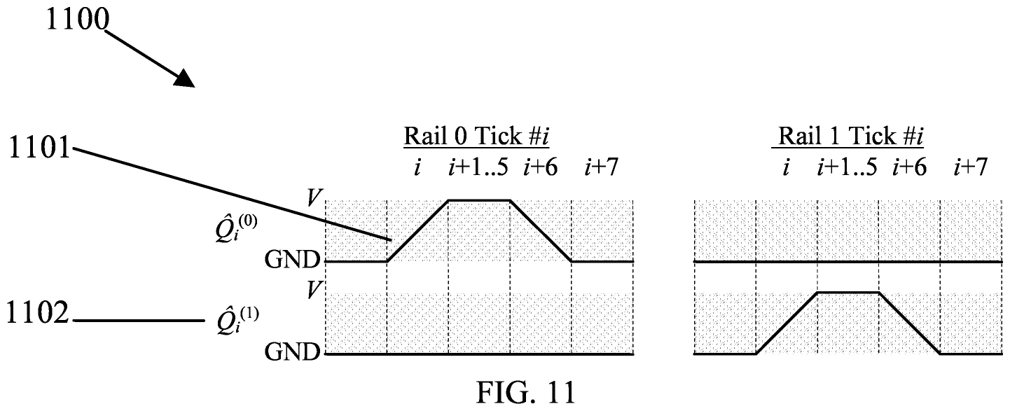

FIG. 11 illustrates a chart 1100 of dual-rail signaling. Each data connection driven by \hat{ϕ}ₗ constitutes two wires designated \hat{Q}ᵢ⁽⁰⁾ and \hat{Q}ᵢ⁽¹⁾. The base wire \hat{Q}ᵢ⁽⁰⁾ has a pulse to V for a 1 as shown and a DC value of GND for a 0. The second rail 1102 is the opposite with a DC value of GND for a 1 and a pulse to V for a 0. Alternatively stated, the first rail carries signal Q and the second rail carries—Q.

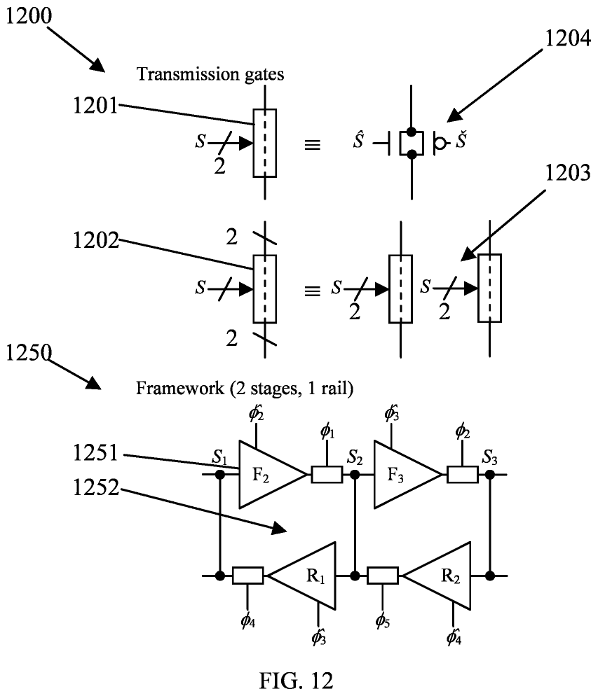

FIG. 12 illustrates the basic circuit 1200 building blocks. Transmission gate symbol 1201 represents a pFET and nFET 1204 connected as shown and driven by electrically complementary signals Ŝ and Š. The dual-rail transmission gate 1202 uses the same symbol but 2-conductor busses and replication 1203 of the dual-rail transmission gate 1202 circuit.

The circuit framework 1250 is illustrated as a sequence of cycles 1252 comprising triangular adiabatic amplifiers 1251 and transmission gates. The relative phase numbers around a cycle 1252, S₁, \hat{ϕ}₂, ϕ₁, S₂, \hat{ϕ}₃, and ϕ₄ are always the same, yet subsequent loops repeat the pattern with the indices incrementing each time, mod 8. The F (forward) and R (reverse) functions, such as F₂ and R₁, can be used to implement gates, provided the functions are reversible.

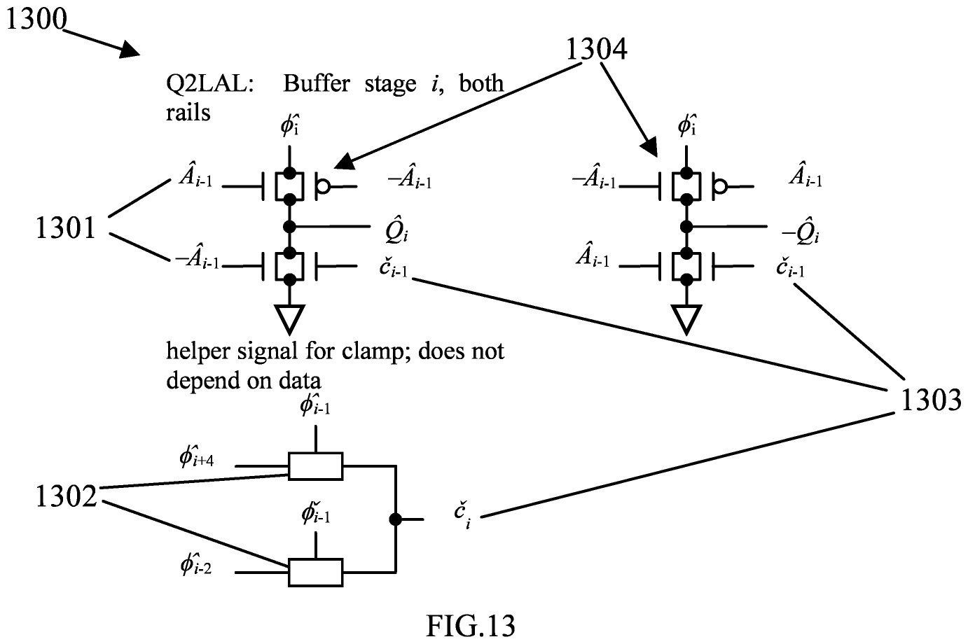

FIG. 13 provides a diagram 1300 detailing the two rails of the adiabatic amplifier 1251, which contains circuits 1304 for each of the two rails. Each of the two rails for phase i, \hat{Q}ᵢ, is controlled by data signals from the previous phase ±Aᵢ₋₁ 1301 and a signal čᵢ₋₁ 1303.

Clamp signal čᵢ 1303 is generated by two transmission gates 1302. The inputs to these transmission gates are just clock phases, making čᵢ independent of data. So, čᵢ can be generated once and used for more than one gate.

The explanation above is specific to the Q2LAL logic family, yet the subsequent discussion applies to other reversible logic families as well, in part because it is implemented by clocking, not the circuit.

Bus Interface

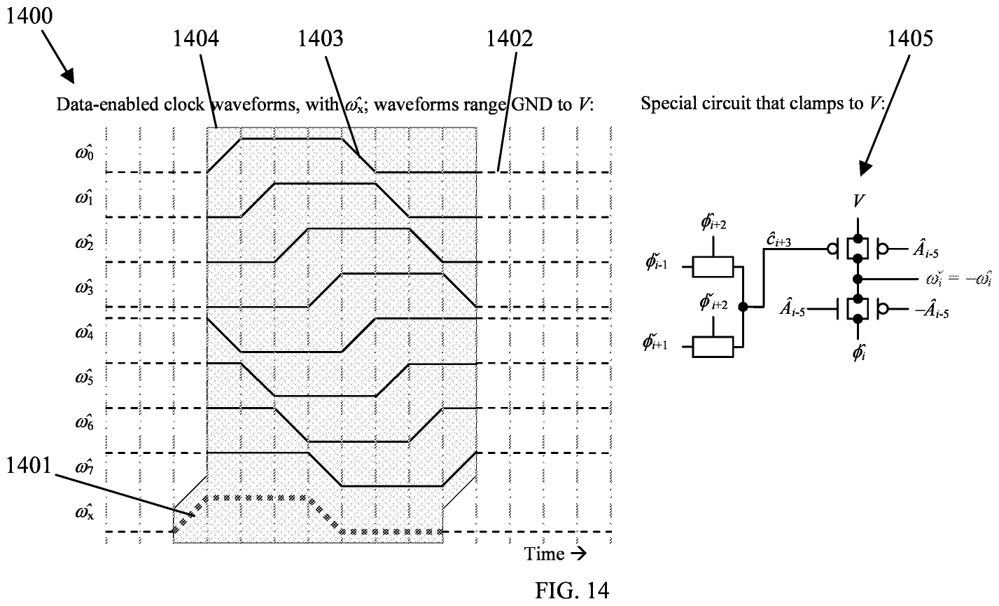

FIG. 14 illustrates the clock waveforms 1400 as augmented to support a bus. Augmented clocks \hat{ω}₀₋₇ in the region 1404 in the center of the diagram are solid lines 1403 and show clock waveforms when running. However, the dashed lines on the left and right show the transition to and from stopped clocks 1402. The data-enabled clock waveforms can be augmented with an additional clock \hat{ω}ₓ 1401 and its electrical inverse \hat{ω}ₓ (not shown), which start and stop one ramp time earlier than the others, as shown by the bend at the bottom of the region 1404.

The Memory Cell

Let us consider the circuit 900 with stopped clocks 1402 resting at the levels indicated. The circular arrow identifies an amplified conductive cycle, creating a memory cell 903. The stopped clocks 1402 indicate \hat{ω}₀₋₃ are low and \hat{ω}₄₋₇ are high. The reader will see that the clocks around the cycle, \hat{ω}₅, ω₄, \hat{ω}₆, and ω₇, all have high values. Signals \hat{ω}₅ and \hat{ω}₆ supply power to two adiabatic amplifiers and ω₄ and ω₇ cause two transmission gates to be turned on.

Special Clock ωₓ to Support Busses

For now, assume the gap 902 indicated in FIG. 9 has been filled and A₀*=A₀. There is no bus interface at this point.

The cycle with a cross through the middle 906, \hat{ω}₁, ω₀, \hat{ω}₂, and ω₃ has all low clocks indicating that the cycle is not a memory cell. However, \hat{ω}₇ enables a transmission gate that drives A₀*=A₀. A₀ is low when the clock is stopped because it is at the reset point in the electrical protocol when it is at the GND level irrespective of data.

However, the additional clock ωₓ 1401 will allow the shift register to drive a reversible bus if suitably connected. Signal ωₓ is dual-rail comprising \check{w}ₓ and its electrical inverse \check{ω}ₓ (not shown). The ωₓ waveform is identical to ω₇ when the clock is running but it turns on and off one ramp time earlier.

Thus, replacing ω₇ with ωₓ at location 907 will have no effect on the circuit's behavior when the clock is running.

Yet, with the replacement and when the clock is stopped, ω₇ will no longer turn on the transmission gate that drives A₀ low. Instead, ωₓ will cause the transmission gate to be an open circuit and A₀ will not be driven.

Since the reversible logic concept assumes all clocks run all the time, FIG. 9 is a valid shift register, even when ω₇ is replaced with ωₓ in the location 907.

However, signal ωₓ will put A₀*=A₀ 902 into a floating state when the clock is stopped, allowing the addition of other reversible logic circuits that drive the bus when other data-controlled clocks are running.

A CMOS tri-state output can drive a bus to 0 and 1 states, but also has a third “tri-state” that does not drive the bus at all. A CMOS bus includes a design constraint that exactly one of the interfaces drives the bus at a time—except during a handoff period where one circuit stops driving and another starts.

The handoff must be designed to avoid electrical conflicts, such as short circuits, that could result if two circuits attempted to drive the bus to different values at the same time.

First, note turning the clock on and off at different times violates existing design rules for reversible logic. Leaving the clock off for an extended period would let A₀ float and device leakage could cause drift to a significant voltage. When the clock is subsequently turned on, the sudden discharge of this voltage would cause a current spike that could disrupt the circuit.

However, two copies of the circuit 900 can create a bus if one interface is driven by the clocks \hat{ω}₀₋₇, \hat{ω}ₓ, and \check{ω}ₓ, and another by clocks \hat{π}₀₋₇, \hat{π}ₓ, \check{π}ₓ, where exactly one of clocks is turned on at every point in time. This would result in one shift register leaving data signals, such as A₀, floating at exactly the times when another shift register drives them. As mentioned above, the voltage on A₀ is low on both sides of the handoff, so there is no short circuit even during the handoff. Thus, the circuits 900 in FIG. 9 create a bus based on a naturally extended set of reversible logic design rules.

It should be noted, the choice of two circuits in the illustration is for convenience only. The method applies to any number of copies of circuit 900, where exactly one of the clocks is turned on at every point in time.

Extensibility of the Bus Interface

The bus interface above has been illustrated with the Q2LAL logic family, but can be applied to other logic families.

The pipeline of cycles in FIG. 9 can be implemented with different numbers of rails, 2 or 3 voltage levels, and so forth. Most of these would accommodate stopping the clock, at least for a brief time, and many would allow a special clocking signal like \hat{ω}ₓ; that would put the gate into high impedance state.

The bus interface can be applied to any reversible circuit, not just shift registers. For example, a bus interface could be put on a logic circuit that calculates the address-line bus value to perform corrections 207. This would involve turning data from the room temperature standard computer 404 or computer 3301 into a qubit number and correction code.

Data-enabled Clock for a Bus Interface

The circuit to generate the clock for each shift register 804 is shown in FIG. 15 as data-enabled clock circuit 1500, which includes clamp circuit 1405, as illustrated in FIG. 14. Shifting a 1 bit into A₋₂ 1501 will produce the waveforms shown by solid lines 1403, although they have been renamed from \hat{ϕ}₀₋₇ to \hat{ω}₀₋₇ and \hat{π}₀₋₇. Shifting in a 0 stops the clock, clamping the waveforms at GND and V.

The first four data-controlled clock signals \hat{ω}₀₋₃ are already available at intermediate positions in shift register as shown. However, the second four \hat{ω}₄₋₇ need to be clamped to V when the clock is off, which are not signal that are otherwise needed. However, clamp circuit 1405 can create these signals.

The new signal \hat{ω}ₓ 1504 is already available in FIG. 15, but its electrical inverse \hat{ω}ₓ also needs to be clamped to V. Circuit 1503 can be the fifth instance of clamp circuit 1405.

Circuit 1500 makes it visually evident that the clock relies on only data signals A₋₂ . . . A₂ and makes no connection to the other Aᵢ signals. The functions Fᵢ and the corresponding functions R₁ that reverse the computation must be the identity function for −1<i<3, i. e. they must be noninverting buffers, otherwise the shift register will either produce incorrect clock signals or not recover energy properly. However, the functions Fᵢ and Rᵢ for 4<i<6 are unconstrained and can be used by the designer to meet other design objectives. In fact, CNOT gates can be placed in this gap later as further detailed herein.

Busses are used in computer architecture to connect many subsystems together over a distance, so busses frequently present a heavy load, typically a capacitive load, which requires greater current handling capability. For the PL/AL architecture, this means some transistors in both the bus interface circuit 900 and the data-controlled clock 1500 should be made wider, or some other accommodation to increase their drive capability. In FIG. 9, there are two such locations 908 and in FIG. 15 at two other locations 1505.

Initializing PL/AL and General Memory

The memory-like structure 850 represents an alternative operating mode where the quantum circuits stored in the PL/AL shift registers can be accessed like a memory. The PL/AL architecture will need this feature to load the registers during system power-up, although memory is useful in many applications. The previous discussion of FIG. 9 assumed A₀*=A₀ 902; this will not be assumed below.

The gap 902 makes A₀* a bus driver and A₀ a receiver. It should be noted that the electrical protocol in reversible logic requires that a receiver recover energy from signals produced by the driver, so A₀ is actively driven at times.

However, there is no reason A₀* 902 must be connected to A₀ 902 instead of some other wire that follows the same electrical protocol. Thus, the circuit 900 can be taken to be a linear shift register whose input is A₀ and output is A₀*.

The memory-like structure 850 is then a circular shift register comprising two segments, a transfer register 852 and whichever of the other N shift registers 853 has its clock enabled.

The state machine 801 in FIG. 8 will always enable the clock on exactly one of the N shift registers, but the transfer register 852 will always be clocked. The single enabled register will act normally while all others will act as isolated static memory cells. Thus, the enabled shift register 853 and the transfer register 852 will swap one pair of bits per clock cycle. Logic associated with the transfer register could use and modify the data, after which the data would be swapped back.

Thus, the data-enabled clock for a bus interface circuit 1500 enables many applications including but not limited to:
1. The memory-like structure 850 is a bank of shift registers addressed by the state machine like a memory. The bank is 9-bits wide by N words deep by the length of each shift register.
2. If the shift registers are one clock cycle long, the memory-like structure 850 becomes the natural reversible extension of a 9×N bit memory.
3. In general, the data-enabled clock and bus interface 1500 can support many of the same applications as tri-state logic in general logic design.

The combined results of the last several sections yield a transistor-based computing system that can be manufactured using a CMOS process and will benefit from CMOS's high density and economy of scale. However, the result improves upon CMOS's energy efficiency through two mechanisms:
1. joule-to-joule transfer from a cryogenic environment to room temperature, saving refrigeration overhead (i. e. β or roughly 300 K/T/ “the Carnot efficiency of the refrigeration system”) and
2. an energy factor of, 2RCIτ over CMOS, i. e. a slowdown factor.

The logic properties extend beyond the universal gates in reversible logic to include:
1. static memory, i. e. data-controlled clocks can stop the clock to circuits being used as memory, reducing dissipation to device leakage levels,
2. busses, i. e. a type of logic that is widely used in standard logic design and due to substantial complexity advantages over implementing the same behavior using universal gates, and
3. energy recovery from the capacitive load on output signals.

State Machine

This section shows how to transform a subcircuit graph into a fully reversible implementation of a state machine. To illustrate the challenge, the subcircuit graph 201 may or may not perform error correction, but the control flow paths subsequently merge at rejoins 209, after which the state machine retains no knowledge of whether it performed the correction and thus cannot reverse its operation. This section shows how to use multiple interacting subsystems to create the effect of one of the subsystems performing an irreversible function but still governed by E_{reversible}=2RCIτ×½CV².

Taken at face value, FIG. 3 shows a continuous stream of information flowing around the circular arrow 406, entering the cryostat as it moves from the standard computer 404 to the cryogenic processor 407. While qubit measurement sends information out of the cryostat as part of the readout subsystem 403, there is no way to erase a bit by turning it into a qubit, which should lead to a buildup of bits in the cryostat that will have to be erased with inevitable dissipation.

While kT is exceedingly small, the minimum dissipation for a transistor circuit to erase a bit is ½ Cₘᵢₙ Vₜₕ², where Cₘᵢₙ is minimum node capacitance to hold a signal and Vₜₕ is the transistor's threshold voltage. In certain applications, ½ Cₘᵢₙ Vₜₕ² is thousands or kT or more.

Stream-In-Stream-Out Method

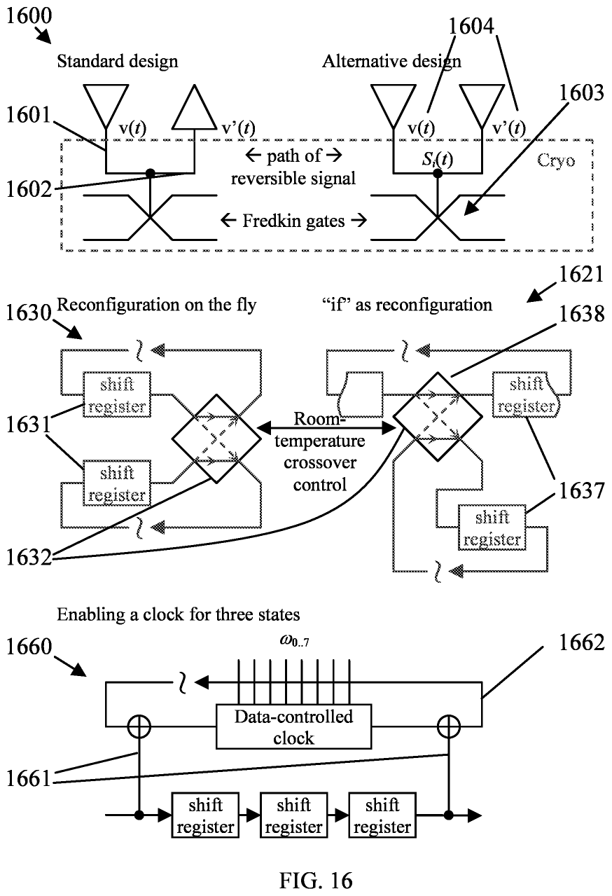

FIG. 16 shows two methods 1600 for avoiding bit erasures in a region of a reversible system. An incoming bit stream 1601, such as qubit measurement results, can be accompanied by an outgoing stream 1602. Since every bit entering the region is accompanied by a bit leaving, the total number of bits that must be stored in memory cells 903 stays the same.

If the region is a cryostat, cryogenic electronics will have to drive a meter-long transmission line from the cryostat to room temperature, and it is likely to have losses that exceed the ½ Cₘᵢₙ Vₜₕ² being recovered.

Two-Streams-In Method

However, the interaction of the external environment with the reversible region is entirely determined by voltage waveforms v(t) and v′(t) at the region boundary 1604. If the outgoing stream contains the same information as the incoming stream, the external environment could create both v(t) and v′(t). The circuitry in reversible region would not know the difference so it would dissipate the same amount of energy.

If there were no delay between the streams v(t)=v′(t) there could be just one wire. We will henceforth call this an external signal Sᵢ(t), Sᵢ(t)=v(t)=v′(t), where i is an identifier to distinguish between multiple such signals.

Externally Controlled Fredkin Gate

If one views the diagram with the two methods 1600 from a distance, one sees an externally controlled Fredkin gate 1603 with cryogenic data and a room temperature control Sᵢ(t) through the region boundary 1604. A Fredkin gate, for reference, swaps two bits when the control is a 1, but has no effect if the control is a 0. Thus, Fredkin gate 1603 could further detail the implementation of transistorized crossover 204 represented by a diamonds 201, whose purpose is to implement branches based on decisions D, based in turn on qubit measurements.

While the stream-in-stream-out method is the only one that applies to information that is not already known to standard computer 404, such as testing and diagnostic information, the two-streams-in method is more efficient and hence preferred. Viewing the two-streams-in method as the control of a Fredkin gate is an effective choice, but other gates may be preferred in other circumstances.

However, the PL/AL architecture 400 must synchronize signal Sᵢ(t) with the power-clocks. Every reversible logic family transfers data over a one- or two-wire electrical protocol. These protocols reset all voltages to GND between the transfers of each bit. For example, the Ŝ₁=\hat{D}₁ waveform 1003 is at the reset level GND during tick 0 irrespective of data. While the exact clock phase and voltage levels vary by logic family, the disclosed implementation of the PL/AL architecture 400 generates both Sᵢ(t) and the power-clocks, creating the constraint that Sᵢ(t) may only change during the clock phase when the Fredkin gate's data wires are in the reset state.

A One-Hot State Machine

Diagram 1630 shows a reversible shift register that can create the effect of “if” statements and loops. Depending on whether crossover 1632 sends signals straight through or crosses them over, the overall circuit will behave as either two independent shift registers 1631 or a single longer one.

The crossover could be the externally controlled Fredkin gate 1603 and implemented by crossover 204. Assuming D changes only when the electrical protocol is in the reset state, each stage will be able to transfer bits to the next stage and recover energy from the previous stage. In other words, the dissipation of circuit 1630 will be the same irrespective of whether it is logically configured as one or two shift registers.

The state machine 801 will be a shift register we will call the state register initialized to a single 1 bit. To explain the terminology, there is “one hot” bit, i.e. a 1, and the rest of the bits are 0. Let us call the one hot bit the state bit and interpret the position or index of the state bit in the state register as the state of the state machine.

By repositioning diagram 1630 as diagram 1621, the circuit diagram becomes geometrically similar to a line of code_1 or subcircuit graph 200. In this equivalence S_{XZZXI} controls whether crossover 1632 switches the bits or connects straight through, with S_{XZZXI}=true, indicating a quantum error, corresponding to crossing over.

If S_{XZZXI} in code_1 is true, the expected behavior is to execute the controlled statement fix_error. This would correspond to crossover 1632 switching the bits, causing the state bit to circulate through both shift registers 1637, executing fix_error once and then the statement following the “if.”

However, if S_{XZZXI} in code_1 is false, the expected behavior is to ignore fix_error and continue execution on the next line. This would correspond to crossover 1632 directing bits straight through. The state bit will stay in one of the shift registers 1637 while the other stays empty.

If a crossover 1632 changes from switching the bits to straight through while the state bit is in the lower shift register, the bit will cycle through the register many times. This implements the while statement in code_2.

Thus, subcircuit graph 201 can be viewed two ways:
1. it was introduced as a graph with boxes and diamonds, which is the common notation in for describing a method or
2. by interpreting the boxes as shift registers, the diamonds as crossovers, and the arcs as wires, the graph becomes a circuit diagram for a machine that implements the method. The circuit will have dissipation E_{reversible}=2RCIτ×½ CV² inversely proportional to clock rate because it is simply a collection of reversible circuit that have this property.

In fact, the discussion above is like compilation of a software program, where a compiler implements a method that transforms algorithms, which are methods as well, into a form that can be executed more directly. The discussion above is also like a computer aided design (CAD) synthesis program that translates the behavioral description of a microprocessor, for example, which is a method, into a netlist which can subsequently be turned into integrated circuit masks, sent to an integrated circuit fabrication facility, and produced as a chip.

Diamonds in subcircuit graphs have one input and two outputs whereas crossovers have two inputs and two outputs, so the process described in the previous paragraph leaves some unconnected wires. These wires will always convey 0 bits during the operation of quantum algorithms, but this may not be true during power-on reset. Therefore, the designer should connect each otherwise unconnected output to an unconnected input.

The Function of the State Machine

The function of the state machine 800 is to enable the clock on shift registers containing AL-bus words so they will affect the qubits.

Say a subcircuit has n time steps, corresponding to an n-stage shift register.

If n=1, the state register could be augmented to become a data-controlled clock. Examining FIG. 15 of clock 1500 and FIG. 9 of circuit 900 reveals that a data-controlled clock is a shift register with some additional circuitry.

Where n>1, the data-controlled clock could be in a while loop with the standard computer 404 causing exit after n clocks using the Sᵢ(t) signal.

The multi-cycle clock circuit 1660 could be used where n≥1. The control bit 1662 will be initialized to 0, starting a 0 continuously circulating through the data-controlled clock 1660, leaving the data-controlled clock off.

When the state bit enters from the left, the first CNOT gate 1661 flips control bit 1662 and turns on data-controlled clock, which will remain on.

After the n=3 single-stage shift registers create an n-cycle delay, the second CNOT gate 1661 flips the control bit 1662 off, shutting off the clock after it has generated n=3 cycles.

The value of n can change by circuit transformation. The n-cycle delay created by an n-stage shift register could also be created by replacing the shift registers with a digital circuit that counts to n before outputting a 1 signal. A subcircuit of n time steps can be reduced to n subcircuits of one time step each, avoiding the need for CNOT gates altogether. This leads to simplification at a different level.

Universal Logic

The two CNOTs 1661 in FIG. 16 are the first use of reversible logic gates in this disclosure.

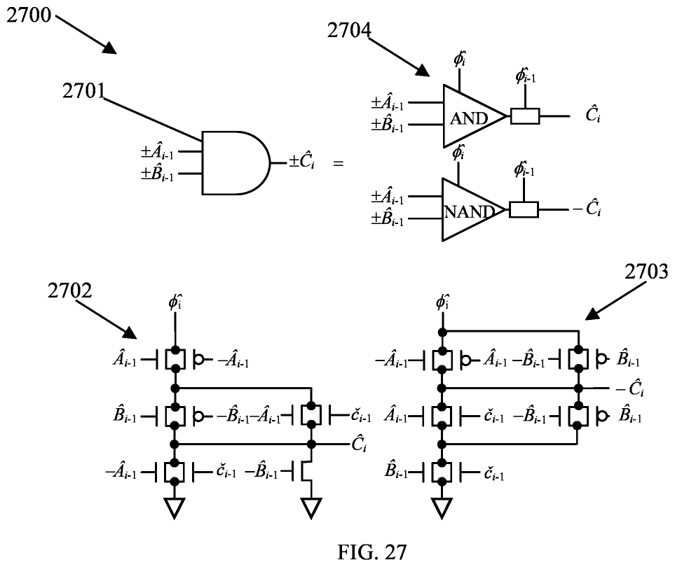

Since Q2LAL signals can be inverted by swapping the signal wires, or rails, AND, OR, NAND and NOR are equivalent up to the labeling of inputs and outputs. An inverter is equivalent to a NAND gate with the inputs tied together. Therefore, universal logic will be disclosed by just disclosing an AND gate. FIG. 27 describes AND logic 2700 based on a 2-input AND gate 2701 implemented by an AND rail 2702 and NAND rail 2703.

The combination 2704 of the AND rail 2702 and NAND rail 2703 use inputs ±Â and ±\hat{B} and define outputs ±Ĉ, all with positive-going pulses. The +Ĉ pulse will appear when there are pulses on both Â and \hat{B} inputs, while the −Ĉ pulse would appear in other circumstances. This is the result of a logical AND.

There are some reversible logic families, such as SCRL, 2LAL, and S2LAL and where a system composed entirely of shift registers needs two rails whereas a system containing universal logic needs four rails. Implementing a four-rail logic circuit has twice as many components, such as transistors and wires, as a dual-rail implementation. Thus, for some implementation options, eliminating the CNOT gates may end up cutting system complexity or component count in half.

Variable Length Shift Registers

Another possibility would be to physically construct shift registers with specific lengths, such as 2^{k}. This would allow transformation of a subcircuit with n time steps into a sequence of physically available shift registers of size 2^{k}. This would allow updating subcircuits post-manufacture, such as for correcting errors in the original design, allowing enhancements, or making an architecture capable of supporting new algorithms.

Generation of the Compressed Data Stream

Recall the objective is to replace the large cable bundle 405 with a smaller one. The standard computer 404 will need to compress information to fit the smaller cable bundle 405 and cryogenic processor 407 will act as a decompressor. At this point in the discussion, the focus is on obtaining a high compression ratio.

The compression method will start with the standard computer 404 initializing a shadow copy of the state machine to its initial state and then modeling the state machine's evolution as it sends signals Sᵢ(t) through the region boundary 1604 to crossovers 1632 that alter the state machine's state evolution sequence. This gives the standard computer 404 a means to transmit decisions D to the diamonds 204 in the subcircuit graph 201.

The explanation in the paragraphs immediately above allows design simplifications.

External signals can be merged. In the absence of adjacent crossovers, discussed below, the single 1 bit can only be in the data path of one Fredkin gate at a time.

This would permit all the Fredkin gates to be controlled by a single Sᵢ(t) 1604, thus reducing the size of the cable bundle. However, “if” statements nested n-levels deep, and some other constructs, can lead to n>1 diamond-to-diamond connections in the subcircuit graph 201 or crossovers 1632 connected output-to-input. If a 1 bit appears on a data line of the first such Fredkin gate, it may appear on the others, so the n Fredkin gates would need distinct external signals, such as Sᵢ(t) . . . Sₙ(t) 1604. The group of crossovers connected output-to-input is just a permutation network.

Multiplexing Circuit

The crossover circuit represented by diamonds 204 would require one cable in the cable bundle per crossover, which could create a scalability bottleneck, but a multiplexing circuit can be applied to reduce the number of wires. Say the cable bundle 405 from the standard computer 404 to the cryogenic processor 407 includes r row wires 1703 and c column wires 1705. This section shows how these r+c wires can create r×c external signals Sᵢ(t) 1604.

The multiplexing circuit will need to be synchronized with the system clocks ϕ₀₋₇, but not necessarily in a 1:1 relationship. The discussion below shows how the multiplexing circuit can run the same speed or faster than the power-clocks while still producing dissipation inversely proportional to τ.

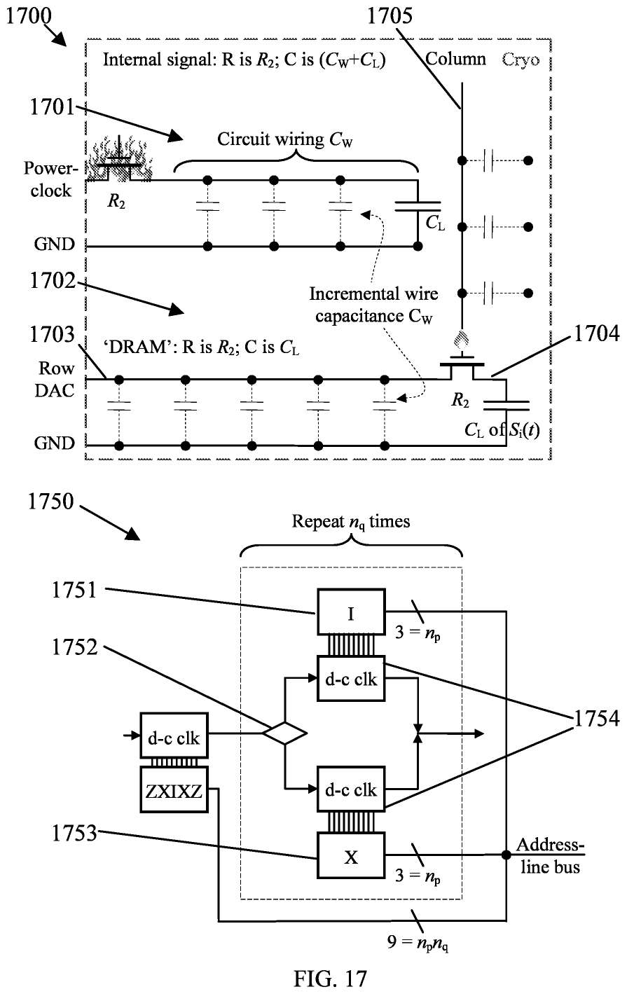

FIG. 17 shows the baseline signal dissipation model 1701 for on-chip reversible transistor circuits. One side of a transistor is connected to a power-clock originating off chip. The transistor charges capacitance C_{W}+C_{L}, where C_{W} is the wire capacitance and C_{L} is the load capacitance. Thus, an on-chip connection exhibits energy factor 2R₂(C_{W}+C_{L})/τ, where R₂ is the transistor's on resistance and τ is the clock's ramp time.

DRAM-like circuit 1702 can send Sᵢ(t) to access transistor 1704 into the cryostat. The DRAM-like circuit will be driven by analog or digital row wires 1703 and digital column wires 1705 coming from room temperature, one of each shown in FIG. 17. Since these wires are driven externally, the R₂'s are external and ½ CwV² dissipation is outside the cryostat.

The access transistor 1704, equivalent to R₂ 505 when selected, should be located physically close to C_{L} so the wire capacitance downstream of the access transistor will be small. This will permit C_{L} to be charged in accordance with circuit 630 in FIG. 6. Thus, an off-chip connection multiplexed via DRAM-like circuit 1702 exhibits energy factor 2RₒₙC_{L}/tₓ, where tₓ is the time of the external signal transition.

The consequence is that the dissipation of the multiplexing circuit has the same inverse time dependence as reversible logic on ramp period τ, but could be faster by a constant factor without an undue effect on dissipation. The eight power-clocks in this disclosure each have a period of 8τ, but the multiplexing protocol could send a new signal in as few as 2 transitions or ticks 1004. Furthermore, chip layout could minimize the length of wire beyond access transistor 1704. This would allow reduction of tₓ without lowering energy efficiency below the level of the rest of the system.

However, the multiplexing option creates possibility that two or more Sᵢ(t) 1604 will conflict due to requiring simultaneous access to different columns or application of different voltages to the same row. In these instances, the standard computer 404 could transmit one of the Sᵢ(t) 1604 ahead of time to avoid a conflict.

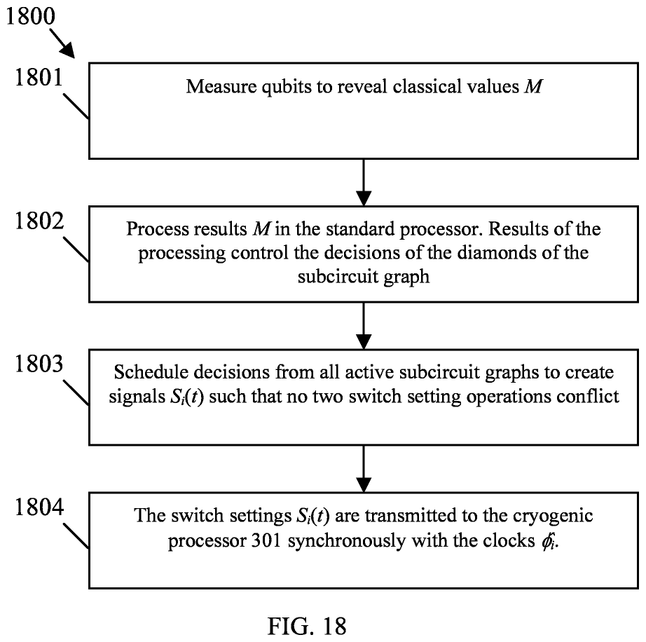

The standard computer 404 uses the method 1800 in FIG. 18:

In step 1801, qubits 402 are measured to reveal values M.

In step 1802, the results M are processed by the classical portion of the quantum algorithm in standard computer 404, such as computing the most likely error that would result in measurement values M. These results are further processed to become the decisions D of the crossovers 204.

In step 1803, decisions from all subcircuit graphs are scheduled into the data streams Sᵢ(t), making sure that no two switch setting operations conflict. The scheduling can control the allocation the Sᵢ(t) 1604 to positions in the crossbar and when to send decisions early.

In step 1804, the Sᵢ(t) signals are transmitted to the cryogenic processor 407 or processor 3303 synchronously with the clocks \hat{ϕ}ᵢ.

Multiple Clock Domains

As illustrated in the magic state factory 300 in FIG. 3, a quantum computer could comprise multiple interacting instances of the system described above.

For example, quantum systems could be physically positioned near each other and interact through boundary qubits 302.

Alternatively, classical reversible circuits with different clocks could be called upon to exchange data. For example, each of the shift registers 802 has a clocking domain that stops relative to the state machine 801. State machine 801 could load initial data into registers 802, but once the clock to register 802 stopped, the interface between circuits 802 and 801 would violate the data transfer protocol.

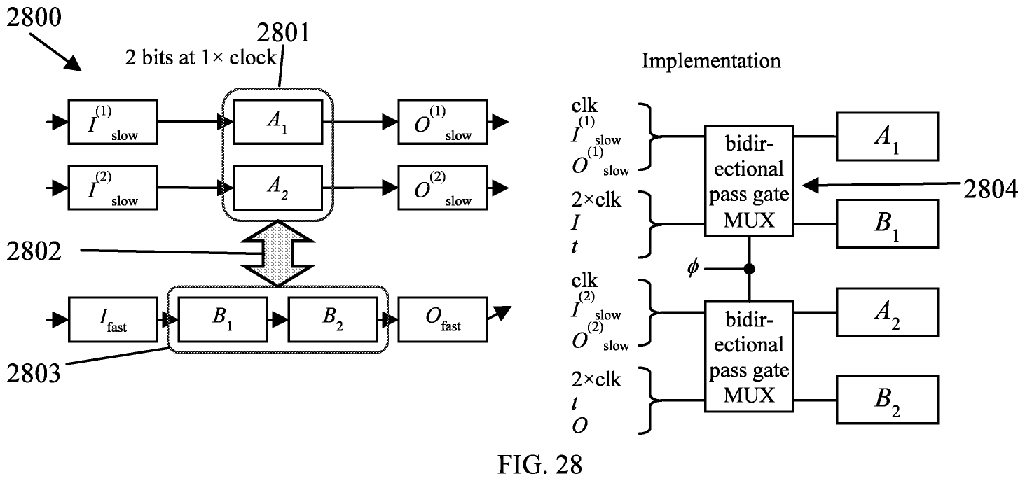

The circuit 2800 illustrated in FIG. 28 can transfer data between Q2LAL domains with different clock rates, including when one domain's clock is stopped. Between ticks 4 and 5, a shift register comprised of 8 Q2LAL stages will store a data bit in its inner stages and the inputs and outputs will be in the resting state of 0. The strategy is to switch all the circuit wiring so the groups of 8 Q2LAL stages swap positions. The circuit schematics for these stages are identical, the only difference being the voltages on internal nodes.

Say we have two Q2LAL domains, first domain 2801 and second domain 2803 running at frequencies f and 2f, as illustrated in FIG. 28. Say the clocks in the two domains are synchronized so that the points between ticks 4 and 5 align periodically. At these points, the two 8-stage shift registers can be “virtually” swapped using bidirectional (transmission gate) multiplexers 2804 addressed by a signal ϕ. The multiplexers would rewire data, clock, and the connection t between the two serial bits from each shift register into the other domain, with the effect that pairs of bits are swapped between the domains. This discussion uses clocks at rates f and 2f as an example, but a different ratio simply leads to swapping a different number of bits.

One 8-stage shift register in each domain is swapped when using a data-controlled clock. If both clocks are running, the circuit swaps the data streams between the circuits. If one clock is stopped, the data stream in the running circuit is simply delayed.

The utility of multiple clock domains is further detailed herein.

Completing the Architecture

Error Correction Units

FIG. 17 shows a representative implementation 1750 of an error correction 207. Like FIG. 3, there are nₚ=3 prime lines and n_{q}=3 qubits, yet the parameters are drawn explicitly to disclose a circuit for different values of nₚ and n_{q}.

To explain the structure in words first, all the boxes in subcircuit graph 201 implicitly operate on the same group of qubits. For correction 207, the subcircuit graph 201 splits into a group of single-qubit subcircuit graphs for one clock period—and then rejoins. Standard computer 404 can then independently direct each of the single-qubit subcircuit graphs to perform a specific correction, or no correction.

Ignoring the bus width indicators and the indication of circuit repetition in 1750, it shows the standard computer 404 transmitting a Sᵢ(t) value to diamond 1752, which branches to one of two data-controlled clocks 1754 each controlling 1-stage shift registers. The registers hold either an I or an X. This implementation of correction unit 208 could either do nothing or perform an X operation, implicitly on all the qubits in the group.

Subdividing the 9-bit bus into nₚ prime lines each operating on n_{q} qubits shows the standard computer 404 transmitting n_{q}=3 Sᵢ(t) values to n_{q} diamonds 1752. This is because the diamonds are within the repetition. Each of the n_{q} copies of the circuit independently branch to the upper branch 1751 or lower branch 1753 branch and by enabling a specific pattern of data controlled clocks 1754, applies an I or X operation to each qubit. This allows the standard computer 404 to specify which qubits receive the X operation through the Sᵢ(t) values.

The correction process could require n_{q} sequential transmissions of Sᵢ(t), which could be implemented with one wire each or one use of multiplexer 1700, yet the multiplexing circuit 1700 offers a more efficient option. If the n_{q} external signals specifying the correction pattern are placed in a single column 1705, then the Sᵢ(t)'s that select the specific correction will appear on independent rows 1703. All the updates will naturally occur in parallel.

For convenience of illustration 1750 shows only a two-way branch diamond 1752 allowing independent I or X operations on each qubit. However, diamond 1750 can be extended to a 4-way branch and the two subcircuits 11751 and X 1753 could become four subcircuits that would permit independent X, Y, and Z corrections to the qubits, or I for no correction.

The one-bit shift registers always contain a 0 or a 1 and can be simplified. The upper branch 1751 shift register is shown for simplicity to be 1-bit shift registers that always contains the same value (0 or 1). By elimination of unnecessary transistors it would end up as a circuit that simply drives a 0 or 1 onto a bus—which will be much simpler than a shift register. However, the specific circuit will depend on the reversible logic family. The same argument applies to lower branch 1753.

Implementation Method

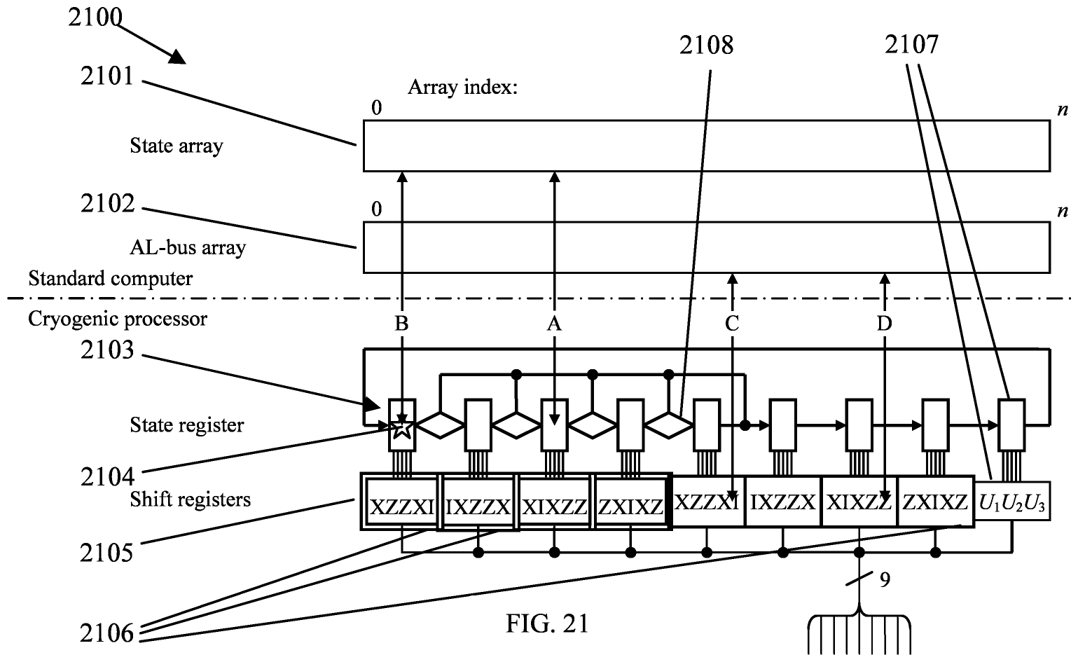

Referring to FIG. 21, we have thus disclosed a method that turns a quantum algorithm into a linear layout 2100 that will implement the quantum algorithm on a set of qubits. The quantum algorithm may be irreversible, but the cryogenic processor 407 follows a natural extension to reversible logic design rules and has dissipation E=2RCIτ×½ CV² characteristic of reversible systems.

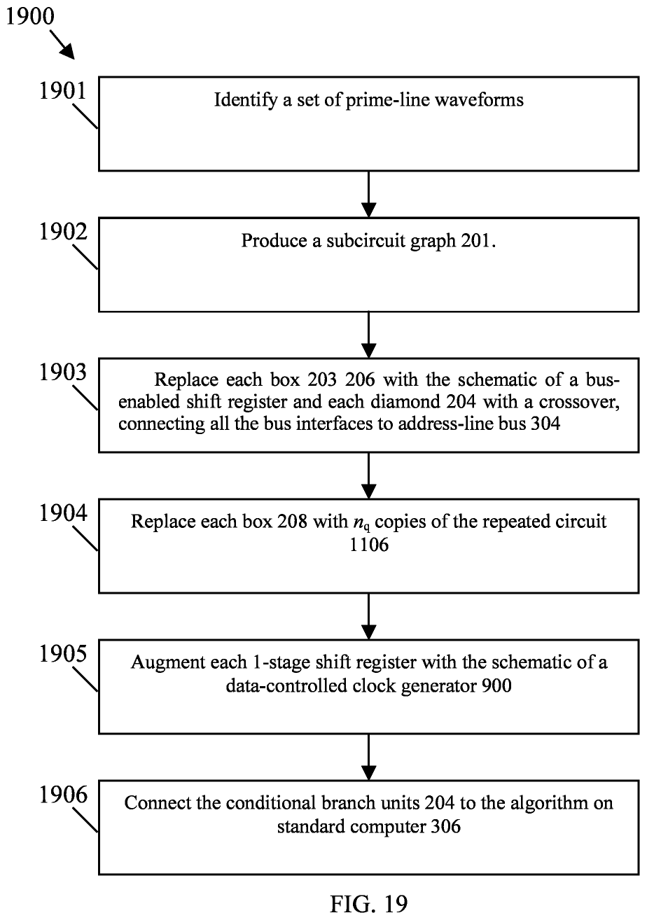

The method 1900 is illustrated in FIG. 19:

In step 1901, a set of prime-line waveforms are chosen from a preexisting set, or a new set is designed based on optimizing the number of prime-line waveforms and controller speed as illustrated in chart 500.

In step 1902, the quantum algorithm is analyzed to produce a subcircuit graph 201. The subcircuit graph includes boxes labeled with fixed gate sequences or subcircuits (such as flagged subcircuit 203) or parameterized gates or corrections (such as correction detail 208) and arcs. Where the gate sequence depends on measurements, the boxes are separated by a diamonds. Arcs connecting the boxes and diamonds represent sequential time flow.

In step 1903, each box is augmented with the schematic of a bus-enabled shift register 900, connecting all the bus interfaces to address-line bus 408. The diamonds 204 are replaced with the crossover circuit, yielding the shift register chain 2106. The AL-bus words defining the subcircuits are placed in an initialization table.

In step 1904, each parameterized gate operation box 208 is replaced with n q copies of the repeated circuit 1750, yielding schematic 2107.

In step 1905, each box is replaced with the schematic of a data-controlled clock generator 1500, connecting the data-controlled clock to the shift register added in step 1903. For n-stage shift registers, n>1, augment the shift register replaced with the schematic of multi-cycle clock circuit 1660 or equivalent. Connect the data controls using the lines in the subcircuit graph, yielding state chain 2103.

In step 1906, the crossover circuits added in step 1903 are connected to the algorithm on standard computer 404 that computes the decision.

The method just described yields a linear layout 2100 and an initialization table. The resulting netlist could be fabricated as a chip, and the chip connected to the AL bus and standard computer. The standard computer 404 would contain software for initialization and operation through a stream of decisions.

Extensions

It is standard practice to have laboratory equipment dissipating multiple watts at room temperature, such as arbitrary waveform generators. The waveforms are sent into the cryostat where they are further processed with non-heat-generating components, such as capacitors, inductors, and (in suitable operating environments) Josephson junctions. This gives some of the effect of having a highly energy efficient waveform generator in the cryostat.

In its full scope, the embodiments includes a method of creating the effect of a highly energy efficient computer in a cryostat.

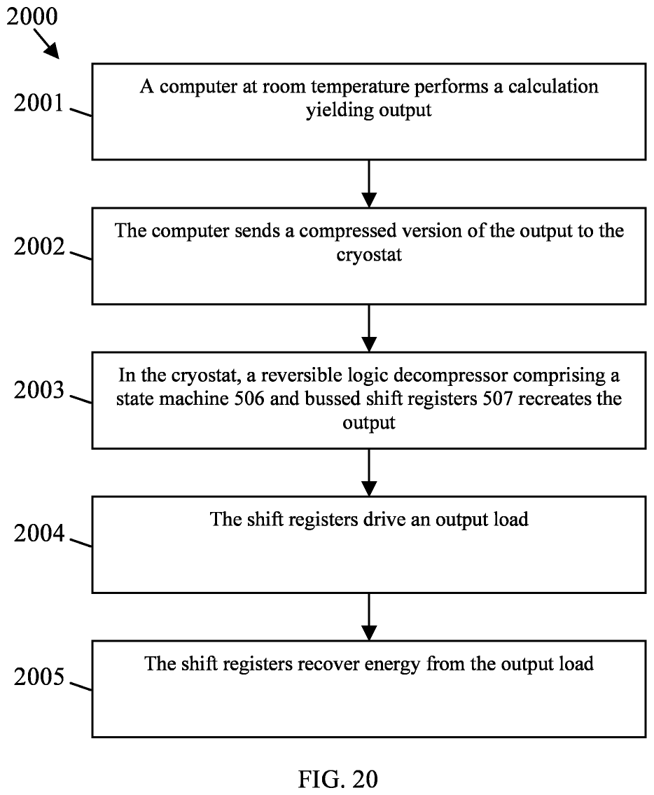

The method 2000 is described in FIG. 20:

In step 2001, a room temperature standard computer 404 does sophisticated calculations, such as analyzing qubit state from the readout subsystem 403 and computing a quantum gate sequence on the fly.

In step 2002, the standard computer 404 compresses outputs resulting from the calculation into a sequence of state machine branches and sends only the branch conditions into the cryostat. In fact, the encoder for a familiar Zip file anticipates a decoder with a pattern memory like reversible shift registers 802 and a state machine 801, with the compressed Zip stream constituting state machine branches.

In step 2003, a decompressor implemented in reversible logic, comprising a state machine 506 and bussed shift registers 507 recreates the output.

Step 2004 accommodates analog output by having digital outputs 408 control a switch matrix 410 comprising individual switches 409. When closed, a prime line signal 401 from the room temperature environment drives one or more output signals.

In step 2005, the bidirectional nature of the reversible logic allows use of method 750 to remove much of the energy involved in setting switches to room temperature before being turned into heat.

Thus method 2000 creates the effect of a computer in the cryostat with dissipation E=2RCIτ×½ CV² that is inversely proportional to speed, as is characteristic of reversible systems. The advantage is the 2RCIτ energy factor.

Power-up, initialization, and execution

Another aspect of the disclosed embodiments is a reset method that will power-up and initialize the classical control system. The issue is that the memory cells 903 will power up to an unknown state, in most cases with multiple 1s in the state register 801 that is supposed to be “one hot.” Shift registers 802 and 803 will contain unknown AL-bus words.

The method operates with stopped clocks 1402 at the DC levels indicated, except that standard computer 404 can single step by generating one cycle of power-clock waveforms 1404 at a time. The first phase of the reset method sets the state machine to a one-hot condition and the second phase takes tour of all the states, loading the shift register as they are encountered.

With a stopped clock, wires A₄ and A₅ on memory cell 903, and —A₄ and —A₅ on the other rail are like SRAM cells. In SRAM engineering, the state of a cell is changed by overpowering the feedback loop in the cell. In this disclosure, the multiplexer's 1700 outputs 1704 are connected to cells 903, also shown as shift register chain 2106, allowing the standard computer 404 to set cells the state register to any state.

The method uses linear layout 2100 and is shown in FIG. 21. The figure shows a state array 2101 and an AL-bus array 2102, both of which are in the memory of standard computer 404 and can be considered additional detail of data memory 3314. Subcircuit graph 201 has been geometrically altered to show vertical alignment, such as at points A-D, to become a state chain 2103. The state machine's initial state is indicated by a star 2104.

Software Shadow Copy of State Within the Cryostat

If the state machine 801 has n states, state array 2101 would be of length n, where each entry represents a bit of the one-hot state register 801. Each bit could be represented as a 0, 1, or X, where X represents the unknown value that appears on power up.

AL-bus array 2102 also has length n, representing the AL-bus output when the state machine is the state with the same index, such as at points C and D. Each entry in the AL-bus array could be an X if the register contents are uninitialized.

Standard computer 404 generates both the power-clocks and Sᵢ(t) values, which will be used to update state array 2101 and AL-bus array 2102 automatically as follows:
1. On each clock cycle, each value in the state array 2101 is moved to the next higher indexed entry unless it is redirected by a crossover 2108. In the latter case, the standard computer 404 can compute the necessary index from Sᵢ(t) values.
2. On each clock cycle, each value in the AL-bus array 2102 would stay put if its clock is disabled, otherwise the value would move to the next higher-indexed entry or backward to the beginning of the circular shift register 2106, shift register 802, or shift register 803.
3. When the standard computer 404 sets a memory cell 903 in the state machine 801 or shift register 802 803, it would change the entry in the corresponding state array 2101 and AL-bus array 2102 to the value set.

In the preferred implementation, the standard computer 404 would continuously maintain a shadow copy of with the entire state of the hybrid hardware 2500, also referred to as system 800. The reset method will be explained as though the programmer was manipulating the hardware through an object-oriented wrapper around the shadow copy. The programmer could use constructs like “index of the first X value in the state register” even though the hardware state register only has 0 and 1 values and the X values are found by the software remembering the history of the state register shifts since power up.

Reset requires two helper methods that move a state bit from index A to index B, initializing AL-bus words encountered along the path in different ways.

MOVE1(A, B) Method

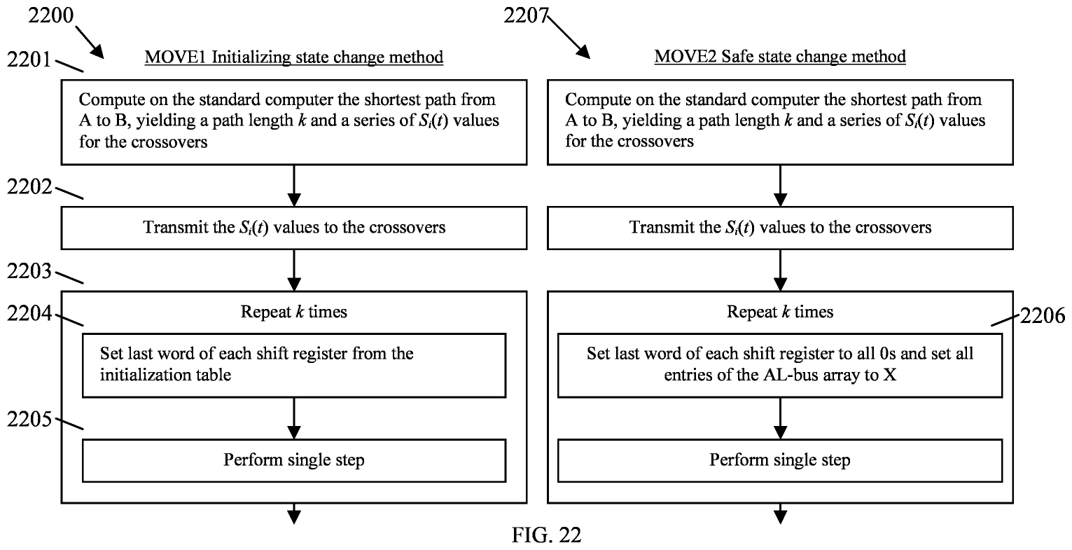

The MOVE1 method 2200 shown in FIG. 22 presumes the state chain 2103 and shadow state array 2101 are in the “one hot” condition with a single 1 bit. This version will also set AL-bus values along the path.

In step 2201, the method 2200 applies a shortest path algorithm for the path between nodes A and B in the subcircuit graph, returning a path length k and a series of Sᵢ(t) values for diamonds 204 and corresponding crossovers.

In step 2202, the Sᵢ(t) values are transmitted to the crossovers implementing diamonds 204.

Step 2203 is to repeat steps 2204 and 2205 k times.

In step 2204, the last word of each circular shift register in the state register chain 2106 is set to the correct value based on the initialization table.

In step 2205, the power-clocks are single stepped.

MOVE2(A, B) Method

The second version is needed after power up when the state register contains unknown bits that are unlikely to be “one hot,” and it resets the state register to the “one hot” condition. This method is like the first version except that it zeros AL-bus values along the path.

The MOVE2 method 2207 is the same as the MOVE1 method 2200 except step 2204 is replaced with 2206.

In step 2206, the last word of each circular shift register in the state register chain 2106 is set to all 0s and the AL-bus array is set to all X's.

If the state machine has multiple 1 bits, multiple shift registers 1452, register 802, and register 803 may attempt to drive the bus to different values simultaneously and cause an undesirable high current. However, the high current cannot occur with stopped clocks 1402 because the bus drivers are limited to driving a 0 or not driving at all.

The mitigation is to set the last word of each circular shift register in the state register chain 2106 to all 0s before single-stepping. Even with this mitigation, multiple shift registers may still drive the bus during a single step, but they will all drive to the value 0, which will not result in a high current.

If the state machine uses unknown, or X values, to enable a shift register, the AL-bus values in the hardware may or may not shift, moving the data in the shift registers to unpredictable positions. The second version therefore sets the AL-bus array to all X's to reflect unknown contents.

Reset Method

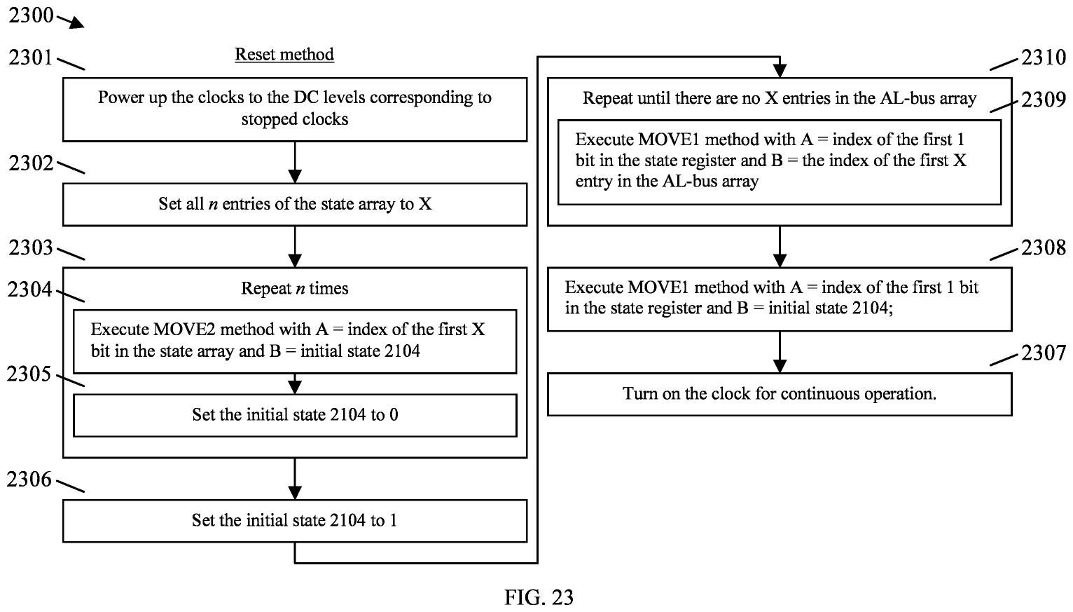

The reset method 2300 in FIG. 23 resets the reversible logic, using the MOVE1 and MOVE2 methods as subroutines.

In step 2301, the clocks are powered up to the DC levels corresponding to stopped clocks 1402. In step 2302, all n entries in the state array are set to X. Step 2303 is to repeat steps 2304 and 2305 n times: In step 2304 the MOVE2 method is applied with A=index of the first X bit in the state array and B=star 2104. In step 2305, the initial state, star 2104, is set to 0. In step 2306, the initial state, star 2104, is set to 1. Step 2310 is to execute step 2309 until there are no X entries in the AL-bus array. In step 2309, the MOVE1 method is applied with A=index of the first 1 bit in the state register and B=the index of the first X entry in the AL-bus array. In step 2308, the MOVE1 method is applied with A=index of the first 1 bit in the state register and B=initial state, star 2104. In step 2307, the clocks are turned on for continuous operation. The reset method ends with the state machine in the initial state and the clocks running.

Simulation

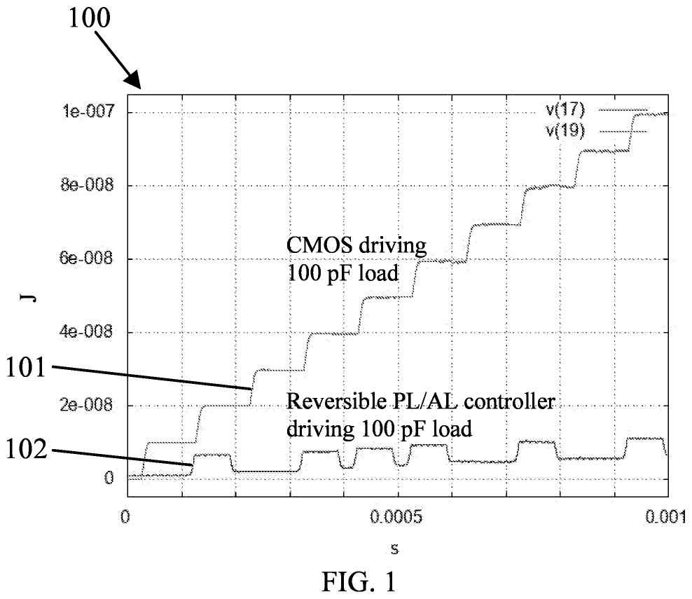

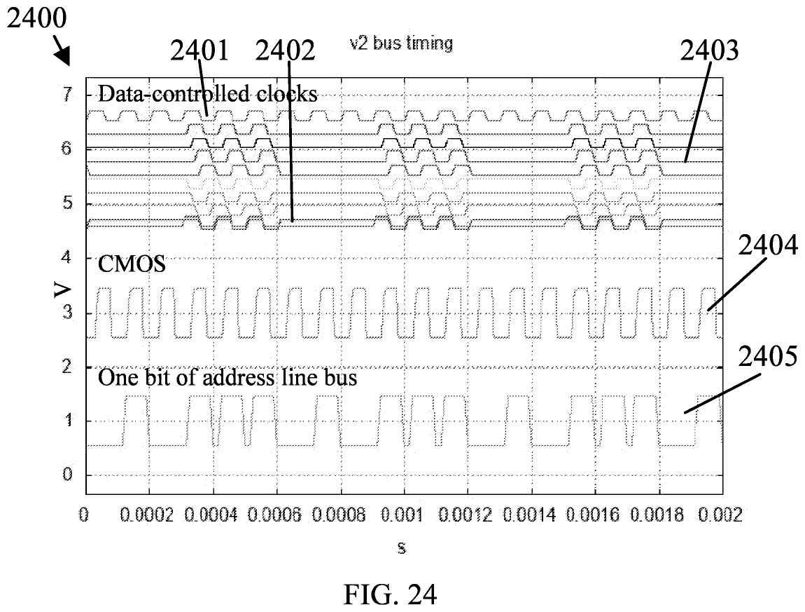

For additional clarity, FIG. 24 provides chart 2400 that shows additional waveforms generated by the Spice simulation of circuits in FIG. 9 and FIG. 15 that produced FIG. 1 and cumulative energy consumption of reversible curve 102. Waveforms in chart 2400 are distinguished from each other by vertical offset for convenience. Also note that the horizontal scales differ between FIG. 1 and FIG. 24.

The topmost trace is \hat{ϕ}₀ 2401, the first phase of the external clock. The nine waveforms below are data-enabled clocks \hat{π}₀₋₇ and \hat{π}ₓ, with the last two in the group \hat{π}₇ and \hat{π}ₓ 2402 appearing on top of each other to emphasize that they are the same waveform when running, but stop at different times.

The circuit simulation producing the chart 2400 includes but does not display \hat{ω}₀₋₇ and \hat{ω}ₓ, which would fill the gaps in \hat{π}₀₋₇ and \hat{π}ₓ, such as at position 2403.

The trace 2404 is the output waveform of a CMOS inverter driving a 100 pF capacitor. CMOS curve 101 is the cumulative energy consumption of the CMOS inverter corresponding to trace 2404.

The trace 2405 is a one-bit address-line bus driving a 100 pF capacitor. The circuit being simulated has two shift registers containing patterns 010 and 111. They are transmitted in an alternating sequence, so the bottom curve comprises three and a third repetitions of each pattern: 010 111 010 111 010 111 01 (with spaces inserted for visual convenience).

The combined result of the last several sections disclose a hybrid computer composed of the novel cryogenic processor 407 connected to a standard computer 404 via a cable bundle 405 that can send data to the cryostat at 1/τ energy levels per bit, subject to restrictions to avoid the cryostat becoming overloaded with information and forced to erase bits. This disclosure also includes how to implement a classical control system using the hybrid computer.

Electrical and Functional Integration

The preceding discussion described how a quantum computer or supercomputer could benefit from the physical principles of reversible logic. However, there are interactions between the function and the physics that must be understood in accordance with the disclosed embodiments.

Even Load

Adiabatic circuits have been developed for computer security purposes that place a very even load on the power supply, such as EE-SPFAL. Q2LAL has this even-load property, but not when data-controlled clocks are used. An aspect of the embodiments includes how the even-load property can facilitate energy management and then generalize the energy management approach to include data-controlled clocks and other non-logic features.

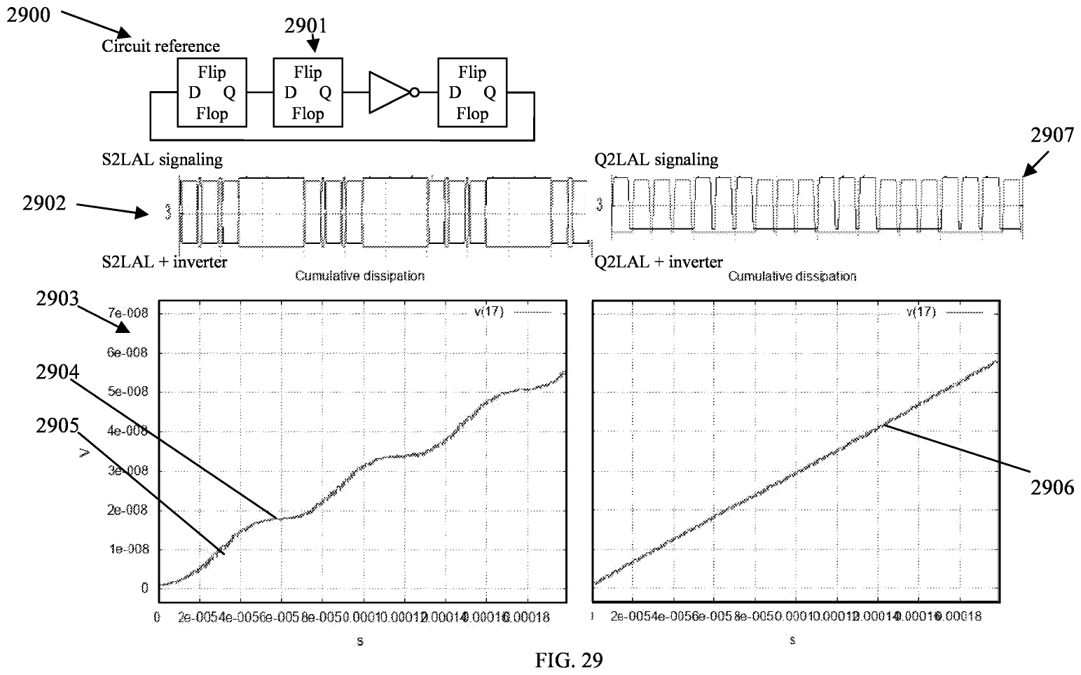

For background, a differential power analysis (DPA) attack attempts to extract secret information from a chip by measuring changes in power supply current. FIG. 29 shows an exemplary circuit 2901 that evolves back and forth between being filled with 0s and 1s and the cumulative dissipation in charts 2903. If processing a 0 consumes a different amount of power than a 1, measuring the power supply current at a particular point in time may reveal the value of certain data bits. While the analysis requires knowledge of the circuit and many trials, attackers find it worthwhile for obtaining high-value information such as passwords.

The reversible logic families S2LAL and Q2LAL are based on similar circuits, but Q2LAL can be engineered to present an even load.

In FIG. 29 flat curve spot 2904 is the cumulative energy dissipation of a S2LAL implementation of exemplary circuit 2901 and the resulting signaling pattern 2902. The flat curve spot 2904 is nearly horizontal when the circuit is filled with 0s, indicating low dissipation, but steep curve spot 2905 rises steeply when filled with 1s, leading to the wavy appearance.

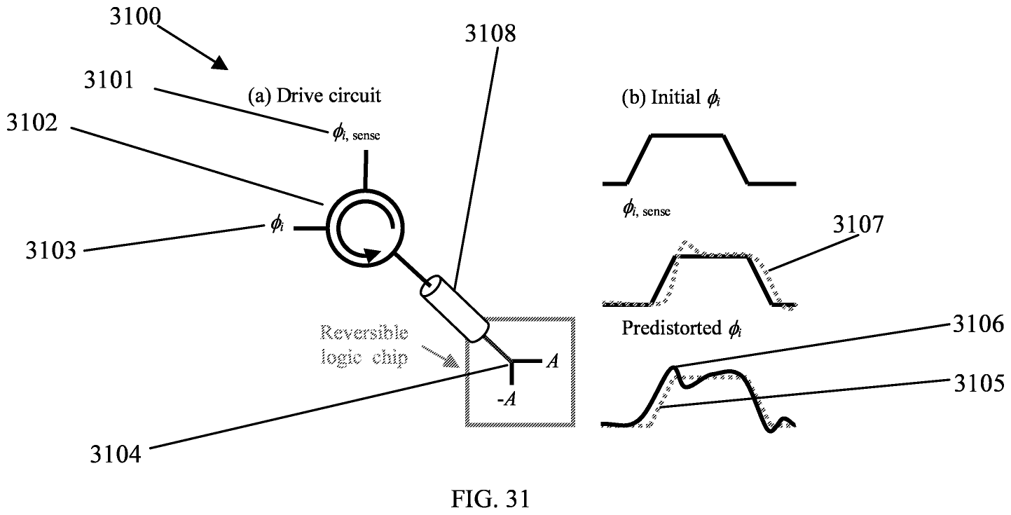

The two paths converging at node 3104 in FIG. 31 differ only by swapping A's with —A's. If the circuits are laid out near each other and have similar geometry, the combined electrical characteristics will be the same irrespective of the data.

Thus, linear curve 2906 is the simulation of a Q2LAL implementation, which has signaling pattern 2907. One would expect a linear increase in dissipation over time, which is true to the resolution of the eye.

Q2LAL would thus be suitable for computer security applications, but its even-load feature can be used to facilitate adiabatic computing.

Noise Issues

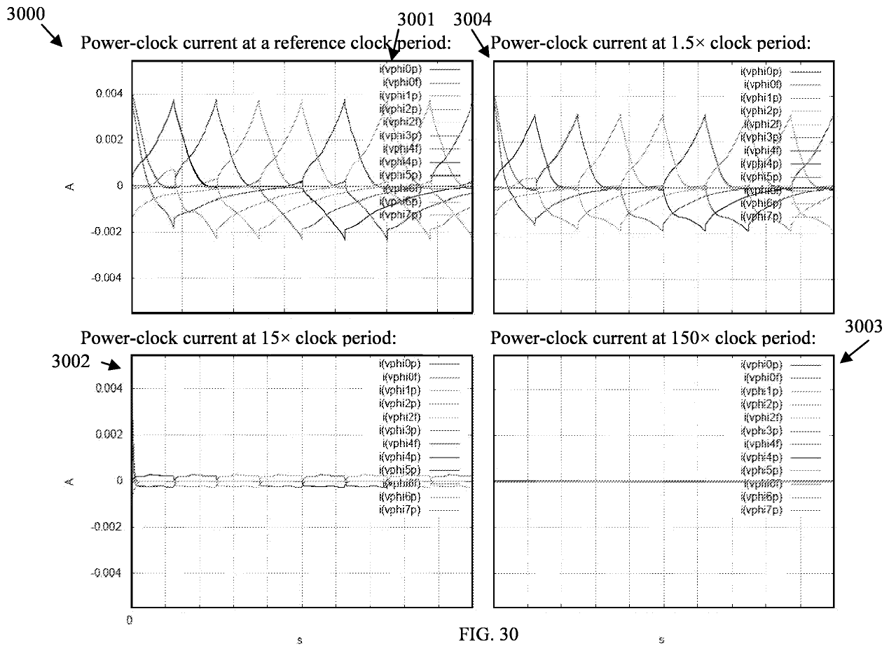

FIG. 30 comprises simulation output charts 3000 of the exemplary circuit 2901 implemented in Q2LAL over a range of frequencies, plotting the current from the 8 clocks. For comparison, the supply current of a CMOS implementation of the exemplary circuit 2901 would show delta functions (narrow spikes) of supply current whenever a signal makes a transition. The width and height of the delta functions does not depend on the clock rate and the bandwidth can be as high as the frequency response fₜ of the transistors.

CMOS fₜ's can be as high as hundreds of GHz, which is higher than qubit control frequencies. So, qubits exposed to CMOS noise would rotate unpredictably, leading to errors. However, Q2LAL has less noise. Q2LAL's noise is also at lower frequencies, which may be below qubit control frequencies and hence less disruptive.

For Q2LAL, FIG. 30 shows a first chart 3001 of the supply current at a clock period appropriate for the default transistor model built in to ngspice (i. e. absolute speed references are irrelevant) and a second chart 3004 shows the same plot at 1.5× the clock period and with a 1.5× horizontal scale. In other words, first chart 3001 and second chart 3004 are logically the same, but time expands. The reader will note that the curves have similar shapes but second chart 3004 has lower amplitude. Adiabatic behavior does not manifest itself at high speeds, so the wave shape and noise are dependent on device characteristics much as they are in CMOS.

FIG. 30 includes third chart 3002 and fourth chart 3003 which show noise decreasing in both amplitude and frequency as the clock period increases further. The circuits and vertical scale are the same as first chart 3001 and second chart 3004, but the clock periods are 15× and 150× longer with corresponding increases in horizontal scale. Just as with chart second 3004, the plots are logically the same, but time has been expanded much more. Curve 30 in third chart 3002 shows that the jagged curves in second chart 3004 were current trying to rise to a certain level. Curve 3002 shows the currents reaching that level and staying there. Fourth chart 3003 looks like a flat line but expanding the vertical scale (not shown) reveals the same waveform as third chart 3002, but at lower amplitude and frequency.

Thus, a “control knob” for managing noise has been disclosed. It should be appreciated that both computing and quantum state are physical processes that consume energy and create noise. If noise above a certain magnitude and in certain frequency bands disrupts qubits, the Q2LAL clock can be adjusted reduce the magnitude, frequency spectrum, or both.

The need to reduce computational noise is far broader than supercomputing and quantum computing. For example, laptops and Smartphones contain a processor and a radio, such as a Wi-Fi or 5G. The radio is isolated from the computation components by shields and filters, yet the radios are not particularly sophisticated. Thus, embodiments herein can apply to electronic devices that include more sensitive radios or radio signals that require more intense processing.

The Adiabatic Powertrain

This section continues the discussion of FIG. 7 that was deferred and shows how to create the power-clocks. The power-clock generators 701 can be assumed to be launching predistorted waveforms into transmission lines 702 further detailed in FIG. 31 as lines 3108 intending that they end up as the power-clock 1001 or power-clock 3105.

FIG. 31 shows the predistortion strategy 3100. A transmission line has two transmission modes that carry waveforms independently in each direction.

A circulator separates the modes. A circulator 3102 is a circuit element with a clean definition and hence convenient for this explanation, yet persons skilled in the art will understand other methods of separating transmission modes that may be more suitable in specific situations.

One mode carries the signal ϕᵢ, sense 3101, which, if properly terminated and with some signal processing, will reveal the actual waveform that was applied to the chip. A power-clock generator 701 would use knowledge of the signal it transmitted, ϕᵢ, sense 3101, and other data, such as the length of the transmission line, to compute the load and the waveform applied to the chip.

A waveform 3103 inserted into the transmission line by the circulator will propagate to the chip using the second propagation mode. After a delay, the waveform will reach the end of the transmission line and encounter the load presented by Q2LAL circuitry, such as at node 3104. Imperfect transmission line termination leads to a reflection back up the transmission line.

Q2LAL power-clocks may go through resistive transistor channels but always end up on the gate of a transistor, i.e. Q2LAL does not include conductive paths between power-clocks or between power-clocks and ground. Transistor gates are capacitors, so the transmission line will have a capacitive termination.

Since all Q2LAL power-clocks end at capacitors, all the charge that comes from the transmission line goes back into it. In fact, for clock periods much longer than the RC time constant of the circuitry, the reflected waveform will have as much energy as the incoming waveform.

The waveform will also be periodic. The discussion around curve 2906 in FIG. 29 shows constant overall dissipation because all logic bits are transmitted in dual rail form 1101 with a pulse on wire A or wire —A but not both, as illustrated at node 3104. Q2LAL implementations should attempt to match the load created by complementary signals by giving them wires of equal length and using other methods to match loading. Given that the loads match, the waveform will be the same every clock cycle even if the 1s and 0s in the circuit are different.

In the idealized case just described, the waveform 3107 appearing at the chip will rise more slowly than the voltage applied by 3103 and then overshoot. Longer transmission lines, larger transmission line impedance, larger load capacitance, losses in the transmission line, and potential filtering of the signal make the distortion more difficult to conceptualize, but its effect can be predicted with circuit simulation or sensed on A sense.

The goal is to compute a predistorted waveform, such as the solid curve 3106 in FIG. 31, which has the property that the predistortion plus the distortion yields the desired power-clock 3105. In less challenging situations, it may be possible to compute the predistorted waveform by simulating the design before it is built.

In more challenging situations, the signal generator could monitor ϕ_{i, sense}, to compute the predistortion. The computation could be performed during system startup or even through feedback during operation.

Thus, it should be appreciated that the power supply drives the computer with a timing lag. The algorithm and hence the application will have inevitable changes in power requirements over time that the discussion above shows how to mitigate and anticipate.

Predistortion and Multiple Clock Domains

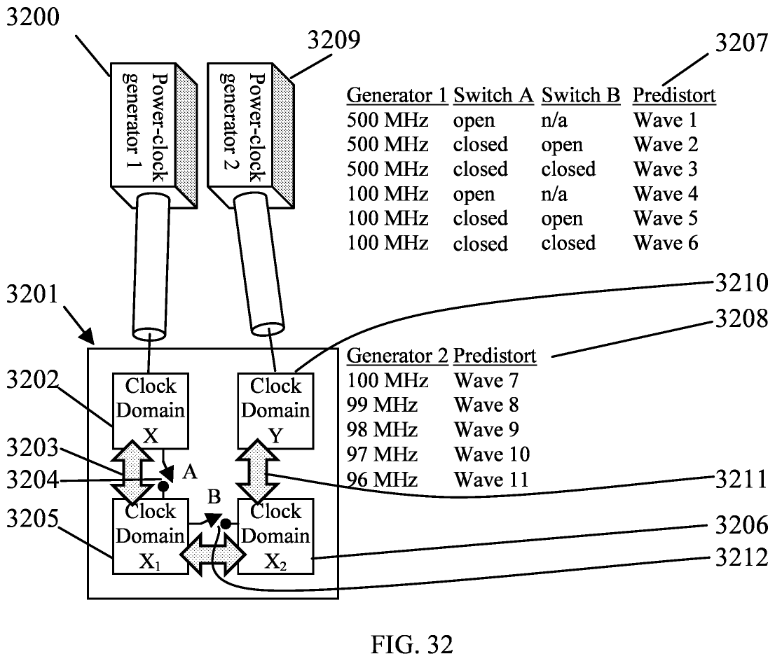

Switching a data-controlled clock on or off, disclosed in FIG. 15, will change the load and make the predistorted waveform incorrect. So, a Q2LAL system can have a system power mode for each combination of clock frequencies. For example, power-clock generator 1 3200 in FIG. 32 connects to three clock domains on reversible logic chip 3201, specifically, domain X 3202, domain X₁ 3205, domain X₂ 3206. Another power-clock generator 2 3209 connects to domain Y 3210. In general, each power-clock generator can produce any frequency f within some range. The domains are in a hierarchy, so a domain can pass its clock at frequency f to a domain below it in the hierarchy. A domain can also use data-controlled clocks as switches, such as switch A 3204 and switch B 3212, passing their clock to a sub domain when the switch is closed or a stopped clock when the switch is open.

The power-clock generators store a predistorted waveform for each system power mode in table 3207 and table 3208. By synchronizing the bits entering the register 1501 of FIG. 15 with similar bits in the power-clock generator, the power-clock generator can switch to the correct predistorted waveform when the load changes.

Domains can exchange data using FIG. 28 circuit 2800 to implement FIG. 32 data pathway 3203 when their clocks are at compatible frequencies. The system power modes and data exchange can work together to create new behaviors for energy efficiency and flexibility of control.

The system modes include the common frequency of 100 MHz in table 3207 and table 3208. This would permit data transfer between domain Y 3210 and domain X₂ 3206 using data pathway 3211. For example, information about quantum errors detected in one domain could flow to another domain that would configure the hardware to correct the error. The data transfer would require both domains to be running at the common frequency of 100 MHz only during the transfer.

Generator 2 3209 has waveforms for 96-100 MHz in table 3208. Let us say, for example, that the predistortion waveform for each frequency is similar enough to the waveform for a frequency one megahertz higher that the waveform generator could create any frequency in the range 96-100 MHz by selecting the predistortion waveform nearest in frequency. Thus, generator 2 3209 would be able to generate an externally defined frequency such as 98,314,159 Hz. This would give the power-clock domain the ability to generate or process control signals tuned to externally defined frequencies. For example, the power-clock domain could be tuned to match the varying resonance frequency in a qubit in motion, where the frequency changes due to Doppler shift, or could be tuned so Q2LAL noise such as in FIG. 30 would avoid qubit control frequencies that could lead to quantum errors.

The power-clock generators could also change frequency based on computational load, similarly to the microprocessor in a laptop changing clock frequency based on software load and die temperature. The advantage is that the system could slow down calculations that are not on a critical path, saving energy or reducing noise.

Thus, it will be appreciated that the power supply load of a reversible logic circuit may vary due to clock frequency changes, but the power-clock generator can compensate, leading Q2LAL in combination with the cryo-adiabatic powertrain to have predictable load.

Automata

FIG. 32 clock domain X 3202 and clock domain X₁ 3205 can also implement automata, such as in FIG. 3 where qubit 304 couples to neighbors yet follows reversible design rules. The clock domain 3206 X₂ at the bottom of the hierarchy could represent an automaton that performs control processes for addition 351 and creation of magic states 352. This automaton would be active only when switch A 3204 and switch B 3212, are both closed.

Clock domain X₁ 3205 in the middle of the hierarchy could be an automaton that creates a magic states via the complex sequence of operations, yet the process would only be active when switch A 3204 is closed. Domain X₂ 3206 could perform addition 351, which needs many magic states 352, so switch B 3212 could be closed only when domain X₂ has a magic state ready for consumption. The addition process would be suspended temporarily when switch B 3212 is open, allowing the two domains X₁ 3205 and X₂ 3206 to exhibit producer-consumer behavior 350.

Thus, the hierarchy of domains shown in 3201, including the switches and data transfer between domains, can be used much like control abstractions in computer programming, such as subroutine calls. While the circuit for the “subroutine X₂” in domain X₂ 3206 always exists as transistors, wires, and potentially qubits on the surface of a chip, its “calling program X₁” in domain 3205 can choose when the subroutine runs by sending a 1 to a data controlled clock 1501 that would essentially close switch B 3212. The calling program also has a mechanism for sending data 2802, like subroutine arguments, and receiving data, like a return value.

Filtering

Regarding thermal noise entering the cryostat through the power-clocks, the preferred solution is to filter frequencies that are not essential to the power-clock waveforms. Attenuation is also possible but would dissipate power into the cryostat and attenuate the reflected signal so it would be more difficult to compute the predistorted waveforms.

If the load is constant, the required waveform will be periodic in both voltage and current so the predistorted waveform can be fixed. The Fourier decomposition of any periodic waveform contains only multiples of the base frequency, such as the 2^{nd}, 3^{rd}, 4^{th}, harmonic. A trapezoidal ramped waveform is anti-symmetric, so it only contains odd harmonics, such as the 3^{rd}, 5^{th}, 7^{th}, and 9^{th} harmonics. However, predistortion is not anti-symmetric and may create even harmonics.

To minimize noise under constant load, each harmonic could in principle be filtered separately with a very narrow pass band. With a 1 Hz pass band and the harmonics in the paragraph above, the Johnson-Nyquist noise power would be 7 kT.

The discussion above illustrates the connection between even load, as illustrated in FIG. 29 by trace 2906, and the engineering of filters for a cryogenic environment. If the load were to vary as indicated by the wavy curve (with flat curve spot 2904 and steep curve spot 2905), a single predistorted waveform would not be sufficient to create the proper adiabatic waveforms. Instead, the best predistorted waveform would vary with time, having higher amplitude during the crest of the wave to compensate for the higher load. This change in amplitude is equivalent to modulation, such as Amplitude Modulation (AM), of the signal being sent through the transmission line. Modulation produces additional frequencies, which would be sidebands at plus or minus the frequency of the modulating wavy curve. The filters 704 can be less selective to include these additional frequencies, which would also allow more thermal noise to enter the cryostat. If the clock domains change at a rate of, say, 1 kHz, the Johnson-Nyquist noise would be 7,000 kT—a lot more than 7 kT but a lot less than the noise accompanying an unfiltered microwave signal used for qubit control.

The criteria above lead to tradeoffs related to filtering. The detrimental effect of room temperature noise entering the cryostat will vary by application. This cost will have to be weighed against the complexity of filtering.

Reconfigurable Architecture

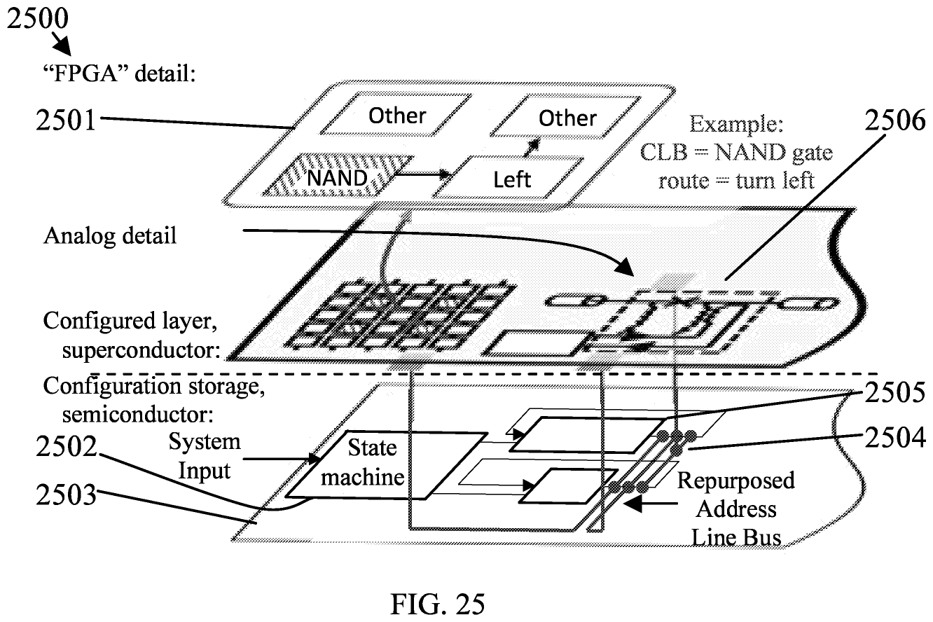

System 800 in FIG. 8, also disclosed as linear layout 2100 in FIG. 21 has the advantage of low dissipation at the price of adequate albeit low speed, yet the hybrid hardware 2500 in FIG. 25 will have the advantage of low dissipation with high speed when needed.

The state machine 801, appearing here as machine 2502, with two registers, register 802 and register 803, appearing here in the lower layer 2503, but drawn in perspective so the address line bus 803 appearing here as bus 2504 moves out of the plane of the chip 2500 to provide space for additional components.

In lieu of controlling the switch matrix 410, the address-line bus 408, bus 803, appearing here as bus 2504 can control other types of devices and circuits. For example, the hybrid hardware 2500 shows digital circuits 2501 and analog circuits 2506 on different physical layers, potentially containing devices based on different technologies.

Field Programmable Gate Array (FPGA) Background

Digital circuit 2501 could comprise an FPGA, in which case it would be an array of configurable logic intermixed with configurable interconnect.

Each logic element in an FPGA can be configured to act as a traditional AND, OR, or NOT gate, although logic elements in production FPGAs are called configurable logic blocks (CLBs) and are equivalent to handfuls of gates that can be configured to be a full adder, a multiplexer, or other functions of similar complexity.

Configurable interconnect is physically implemented as a regular structure of interconnect segments joined by configurable switches that can be programmed to send a signal, for example, straight ahead, to the left, to the right, to the nearest CLB, etc. This gives the effect of being able to change a chip's netlist after manufacture by reconfiguring the switches.

Traditional FPGAs are configured by clocking an n-bit string into a shift register. Each of the n internal shift register stages provides a wire that configures a CLB or switch. Shifting in a new string reconfigures the FPGA. Some FPGAs can reconfigure themselves on the fly, such as the left half of an FPGA reconfiguring the right half; for example, from a 5-bit error decoder 201 to an integer multiplier.

Repurposing the Address-Line Bus

Say the PL/AL implementation 2505 corresponding to architecture 800 produces an n-bit address-line bus 2504 corresponding to bus 803 that can be changed in parallel by the standard computer 404 sending Sᵢ(t) signals to the state machine 2502 corresponding to state machine 801. There is no requirement that the n bits be interpreted as an AL-bus word, so some of the bits could instead control analog circuits 2506 such as switches, modulators, and D-A converters. These circuits could be used for purposes not requiring especially low dissipation, such as self-testing and calibration of quantum hardware.

Likewise, the n bits could be used to configure an FPGA-like device 2501 in lieu of wires from the n-bit shift register. This would make a small amount of reconfigurable digital logic available in the classical control system.

Furthermore, state machine 801 could reconfigure digital 801, considered as an FPGA-like device, into a large amount of digital logic by changing classical logic circuits over time similarly to the way subcircuit graph 201 creates a sequence of quantum subcircuits over time. An input signal Sᵢ(t) would initiate reconfiguration through a crossover implementing a diamond 204, changing to a different configuration.

JJ-SFQ Circuits

A hybrid of reversible transistor circuits and JJ-SFQ could combine the strengths of the two technologies, specifically the fact that transistors are small but JJ-SFQ circuits are fast.

The energy per operation of reversible circuits is proportional to speed, due to E_{reversible}=2RCIτ×½ CV², but JJ-SFQ circuits have low energy per operation even at high speeds. This opens the door to a hybrid solution where transistor circuits would provide a wide but slow AL-bus which the JJ-SFQ circuits would transform into a narrower andt faster bus.

JJ-SFQ technology includes both Single Flux Quantum (SFQ) digital gates and analog circuits that use Josephson junctions (JJs) in a diverse range of circuits, such as an analog switch 2506 or an RF/microwave modulator such as may be necessary to control qubits. These analog circuits can include SFQ digital controls to, for example, open or close the analog switch. This would allow JJ-SFQ be become a higher speed alternative to the HEMTs 409 that switch prime-line waveforms.

Devices are also available for translating the voltage-based signals used in transistor circuits to and from the current-based signals characteristic of Josephson junctions, including standard transistors, superconducting FETs, and nTrons.

Fast Address-line Bus

Structure 2500 can be configured to make a classical control system that has a shorter reaction time than the PL/AL architecture 800, yet with similar dissipation. Reaction time is the time between a qubit measurement and the earliest change in a control signal applied to a qubit. Reaction time is like conditional branch latency in a microprocessor.

Prime lines 502 are sparse, offering the opportunity to synthesize prime lines indexed 1-4 from the single prime line indexed 1 in prime lines 501. FIG. 4 showed that this could be done by decreasing the prime-line waveform period and the power-clock period τ by 10×. This method would increase dissipation quadratically, i.e. 100×, so a more energy efficient solution may be desirable.

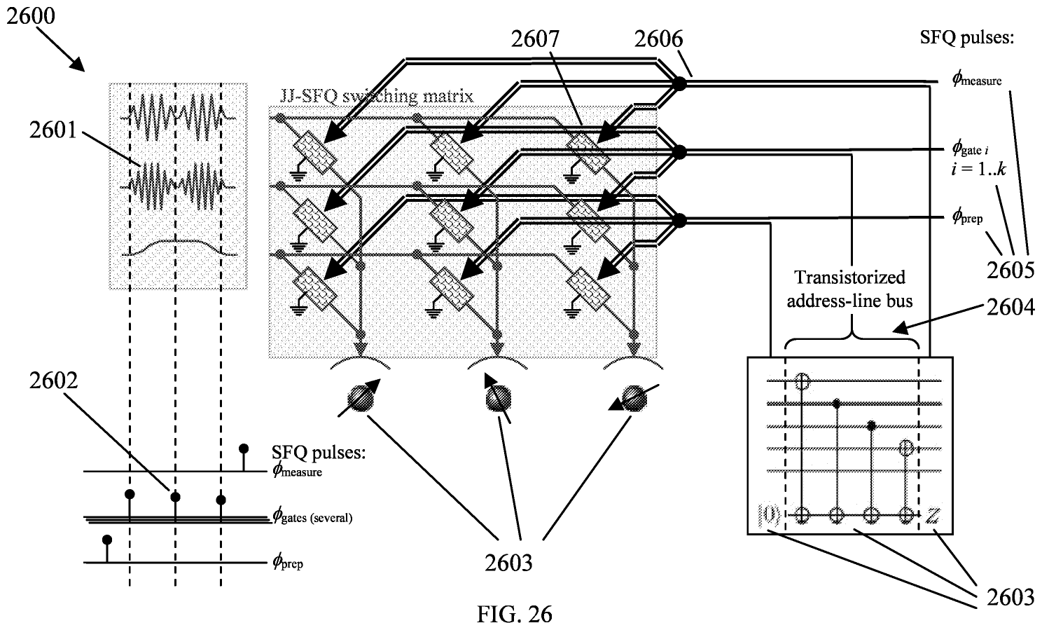

As illustrated in FIG. 26, subsystem 2600 splits the address-line bus into a transistorized address-line bus 2604 and a fast address-line bus 2606.

The transistorized address-line bus could represent unflagged subcircuit 206, shown in the present context as subcircuit 2603, which includes preparation, k=4 levels of gates, and measurement.

The bits of the transistorized address-line bus are divided into groups defined by fast clocks 2605 based on the time within the clock period when they influence the qubits.

Each prime-line waveform 2601 would comprise one or more sub waveforms that can control qubits, but several sub waveforms could appear at different times, each enabled by an offset pulse 2602, essentially equivalent to time offsets 501.

The fast clocks 2605 can be gated with the transistorized AL-bus 2604 to mark the beginning of each sub waveform, designated ϕₚᵣₑₚ, ϕ_{gate i}, i=1 . . . k, and ϕₘₑₐₛᵤᵣₑ.

To reduce the size of the cable bundle 405, each prime line 2601 contains multiple sub waveforms, each controlled by a signal in the transistorized address-line bus. However, the address-line bus is local to the cryogenic chip 703, so having a wide address-line bus is not overly costly.

This disclosure previously showed how to switch a HEMT 409 efficiently by creating a fraction-of-a-volt control signal via a circuit 504. However, switching such a large voltage using circuit 504 is only efficient at lower speeds.

Efficiently switching the fast waveforms, such as for gate operations, is possible with JJ circuits 2506, such as a microwave switch, which could become the switches 2607.

The method illustrated is to combine fast SFQ signals ϕₚᵣₑₚ, ϕ_{gate i}, and ϕₘₑₐₛᵤᵣₑ 2605 with signals from the slower transistorized address line bus to create the fast address-line bus. Enhanced switches 2607 would interpret information in the AL-bus words 2604 as specifying not only a specific prime-line waveform 2601 but also which fast ϕ signal 2605 defines a time window within the waveform. The prime-line waveform 2601 would only be enabled during this time window. This would allow parallelism in the AL-bus words to mimic the effect of faster reversible logic clocks without increasing the speed of the clock and avoiding the quadratically higher dissipation.

A Reconfigurable Fast Address-Line Bus

The fast address-line bus 2606 could be implemented as hardware directly or as reconfiguration of the FPGA-like structure 2500.

FIG. 26 is a block diagram fabricated using reversible logic for the transistorized address-line bus 2604 and a faster technology, such as JJ-SFQ, for the fast clocks, gates 2605, and switches 2607.

Alternatively, the fast address-line bus 2606 could be implemented by reconfigurable gates 2501 and the switches could be the configurable analog circuits 2506. The advantage of this approach is that many customizations could be performed after manufacture, so the method described in FIG. 19 can be applied both before and after manufacture.

For example, the numbers of gate levels k in a subcircuit, represented by the number of fast clocks 2605 k, could be changed after the quantum computer has been manufactured, thus allowing low-level quantum behavior to be upgraded over time or optimized for specific applications.

Analog Front Ends

Enhanced switches 2607 represent of a class of analog front ends. The objective of an analog front end is to interface between information in three forms, classical digital, classical analog, and quantum information. The common characteristics include the mixing of analog prime lines and digital control to produce a more complex analog signal.

Analog front ends more sophisticated than the HEMT 409 may have multiple digital controls that can alter the prime-line waveform to some extent. For example, a binary switch could either connect a capacitor to ground or leave it floating, thereby adjusting the amplitude or phase of a prime line to meet the needs of an application, offset manufacturing variance, or mitigate the effects of aging.

For this reason, switches 2607 replace the HEMT with an analog module driven by multiple digital control lines, one or more clocks to identify the sub interval, and a ground connection that would enable functions such as filters.

However, the front end can be extended with varying numbers of signals of different types, whether by fabricating a chip where the front end is part of the chip or by configuring the FPGA-type logic or analog blocks disclosed.

Extension of the Embodiments

Thus, subsystem 2600 merges three technologies. The control of a quantum computer is complex, requiring a large memory, complex logic circuits, or a combination of the two. Aspects of the disclosed embodiments include how to apply reversible logic, which is based on physically small transistors and dissipates little energy. However, the lowest dissipation only occurs when reversible transistor circuits run slowly. Quantum signals related to qubit measurement are slow but other signals are much faster.

So, a second technology, using JJ-SFQ as an illustration, temporally interleaves the transistorized address-line bus to create a faster data stream for a smaller number of prime lines. Even though Josephson junctions are physically large, using them is reasonable because interleaving logic requires far fewer devices than the memory needed to hold the data that is to be interleaved.

The third technology is the prime lines. These analog signals are expensive because they have a complex wave shape with additional analog features such as low noise and extreme timing precision. When generated at room temperature, they add to the cable bundle entering the cryostat. In this disclosure, the prime lines can be created at room temperature where energy, space, and device count are less expensive. However, the number of prime lines is minimized through temporal multiplexing.

The JJ-SFQ and transistor technologies used for illustration could be replaced by many combinations of fast and slow electronic technologies. Other fast and slow technologies include transistors operating at different speeds, such as reversible circuits with different values of r and CMOS circuits. The ideas also apply to JJ circuits other than SFQ, such as Adiabatic Quantum Flux Parametrons and the ideas also apply to other devices altogether.

Top-Level System

In certain embodiments the aspects above become one of many modules in a scaled up quantum computer. A quantum computer may comprise multiple subcircuit graphs 301, often located or depicted on a 2D surface. At any point in time, a group of qubits may be involved in an operation such as addition 351, magic state preparation 352, rotations 353, quantum error correction 201, or other operations based on textual representations such as code_1 and turned into a quantum circuit through the processes in this disclosure.

Thus, this disclosure anticipates that a cryogenic processor 407 will operate on multiple instances of subcircuit graph 200, including multiple different subcircuits.

A subcircuit graph 200 and others like it will take a different amount of time to execute based on qubit measurements and the resulting decisions. The fact that the subcircuit graph 200 and, in general, any subcircuit graph, takes a variable amount of time to execute means that the cryogenic processor 407 will have to accommodate asynchronous operation of multiple subcircuit graphs 200.

Subcircuit graphs 200 may interact with other subcircuit graphs through boundary qubits 302. One subcircuit graph may have a “CNOT control” on one side of its boundary qubits while another subcircuit graph has a “CNOT target” on the qubit across the boundary yet within the necessary physical proximity to engage in a two-qubit operation. These two subcircuit graphs could act together to create a two-qubit operation, provided the two subcircuit graphs perform their complementary operations at the same time.

In some preferred implementations, the subcircuit graph 200 could become an instruction set. Subcircuit graphs for several algorithms could be connected by a diamond 201 that acts as an instruction dispatcher. Once implemented on a quantum computer, the standard computer 404 could specify the instruction dispatch decision and change the behavior between error correction, rotations, arithmetic, and other functions that could be created with the method in this disclosure.

While quantum computers nascent themselves, they will get their performance from the qubits rather than the control electronics, so there will be little motivation to make control electronics faster than required by the qubits—particularly if speed harms qubits through dissipation or noise. The term 2RCIτ could be of rough order of magnitude 1/1,000 for quantum computers.

The disclosures herein include an adiabatic powertrain that could be of benefit for both room temperature and quantum applications. Furthermore, at cryogenic temperatures, a novel joule-to-joule transfer of energy from the cryostat to room temperature eliminates the need for an energy recycling power supply.

This disclosure further describes an architecture for a classical control system that performs the functions that need to be performed in the cryostat in a reversible manner and hence yield the potential 2RCIτ energy efficiency. This architecture is nothing like a microprocessor, but is essentially a data decompressor for the output of a microprocessor located somewhere else. Key portions of this architecture have been simulated at the transistor level and some output graphs appear in this disclosure.

This disclosure includes circuits that reduce overhead. Reversible logic gates have many more transistors than the equivalent function in CMOS, leading reversible logic gates to be inefficient due to “overhead.” The disclosed embodiments are not based on creating drop-in replacements for logic gates, but rather reversible memory and busses. This new approach is a better match for a hybrid system with a conventional microprocessor and a reversible “decompressor.”

The embodiments include a method for transforming a quantum algorithm into a schematic diagram of a classical control system that would execute the algorithm, which is a synthesis design tool.

Quantum Computers

Hybrid quantum computer system 3300 can be a standalone system or a co-processor to a server such as server 3401, depending upon design considerations. Computer 3300 is implemented with standard computer 3301 connecting to standard program memory 3315, volatile or data memory 3314, non-volatile storage 3313, some forms of which are removable 3306 while others are non-removable 3307. Standard computer 3301 may include non-quantum, or classical, communications connections 3311, which are generally divided into input 3308 and output 3310. Input and output may function as a graphical user interface (GUI) 3309.

If computer 3300 includes quantum computing capabilities requiring cryogenic operation, the standard processor 3301 will connect to a cryogenic non-quantum, or classical, processor 3303 via a cable bundle 3302 and provide an interface to qubits 3305. The cable bundle may be implemented with wire, fiber, free-space, or a similar technology depending on design considerations. In some cases, quantum information on qubits 3305 will be read out by measurement subsystem 3304 that may convey data to the standard processor 3301, often enhanced with special signal processors 3301. In other embodiments, the measurement subsystem 3304 transmits data to the cryogenic processor 3303.

The quantum processor may include direct quantum I/O 3312 which may connect to a quantum internet 3404 but may also include interface for sensors producing or sensing quantum information, such as entangled qubits.

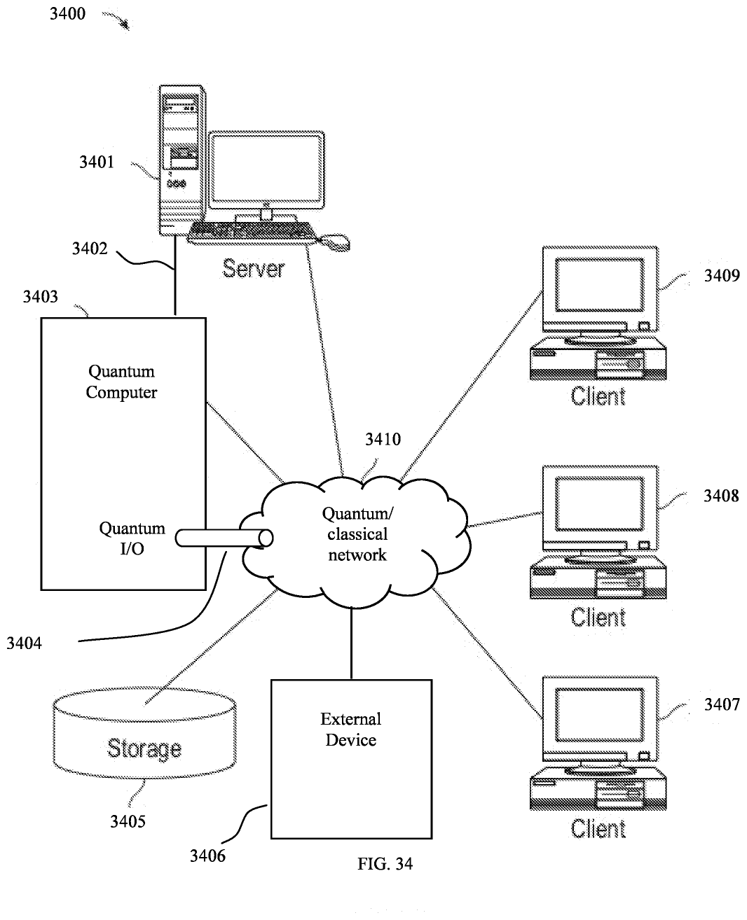

In the example depicted in FIG. 34, server 3401 provides data such as boot files, operating system images, applications, and application updates to clients 3409, 3408, 3407 and/or quantum computer 3403 3300. Clients 3409, 3408, 3407 and quantum client 3403 and external device 3406 are clients to server 3401 in this example. Network data-processing system 3400 may include additional servers, clients, and other devices not shown. Specifically, clients may connect to any member of a network of servers, which provide equivalent content.

In the depicted example, network data-processing system 3400 is a part of the Internet with network 3410 representing a worldwide collection of networks and gateways that use the Transmission Control Protocol/Internet Protocol (TCP/IP) suite of protocols to communicate with one another. At the heart of the Internet is a backbone of high-speed data communication lines between major nodes or host computers consisting of thousands of commercial, government, educational, and other computer systems that route data and messages. Of course, network data-processing system 3400 may also be implemented as a number of different types of networks such as, for example, quantum data communications, sometimes called the quantum internet, an intranet, a local area network (LAN), or a wide area network (WAN). FIG. 33 and FIG. 34 are intended as examples and not as architectural limitations for different embodiments of the present invention.

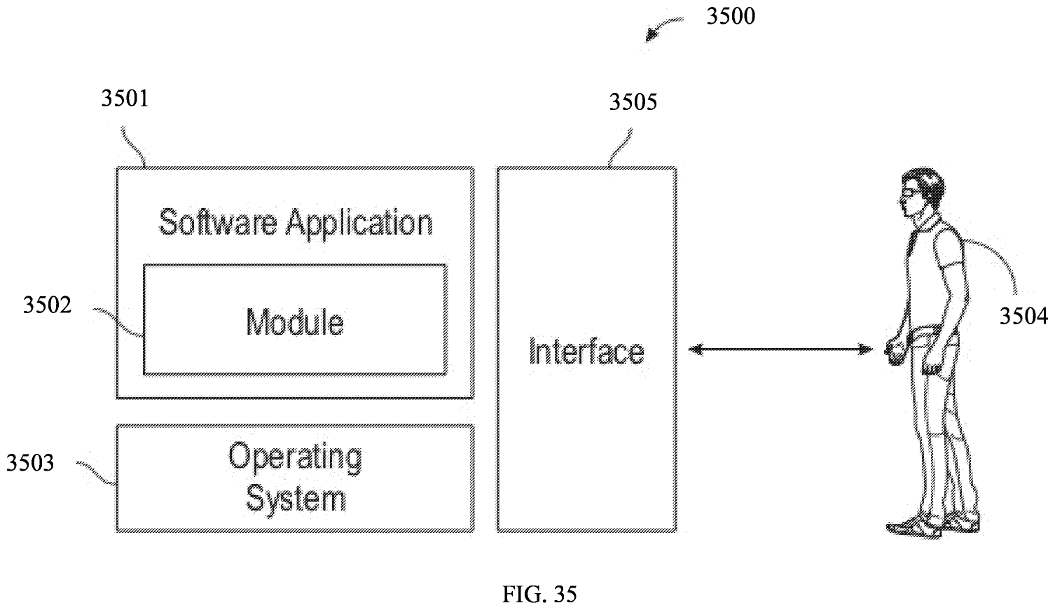

FIG. 35 illustrates a software system 3500, which may be employed for directing the operation of the data-processing systems such as computer system 3300 depicted in FIG. 33. Software application 3501 may be stored in memory 3317, on removable storage 3306, or on non-removable storage 3307 shown in FIG. 33, and generally includes and/or is associated with a kernel or operating system 3503 and a shell or interface 3505. One or more application programs, such as module(s) or node(s) 3315, may be “loaded” (i.e., transferred from non-removable storage 3307 into the memory 3317) for execution by the data-processing system 3300. The data-processing system 3300 can receive user commands and data through user interface 3505, which can include input 3308, output 3310, or a GUI 3309, accessible by a user 3504. These inputs may then be acted upon by the computer system 3300 in accordance with instructions from operating system 3503 and/or software application 3501 and any software module(s) 3315 thereof.

Generally, program modules (e.g., module 3315) can include, but are not limited to, routines, subroutines, software applications, programs, objects, components, data structures, etc., that perform particular tasks or implement particular abstract data types and instructions. Moreover, persons skilled in the art will appreciate that elements of the disclosed methods and systems may be practiced with other computer system configurations such as, for example, hand-held devices, mobile phones, smart phones, tablet devices, multi-processor systems, printers, copiers, fax machines, multi-function devices, data networks, microprocessor-based or programmable consumer electronics, networked personal computers, minicomputers, mainframe computers, servers, laboratory equipment, sensor systems (including sensors systems in space),medical equipment, medical devices, and the like.

Note that the term module or node as utilized herein may refer to a collection of routines and data structures that perform a particular task or implements a particular abstract data type. Modules may be composed of two parts: an interface, which lists the constants, data types, variables, and routines that can be accessed by other modules or routines; and an implementation, which is typically private (accessible only to that module) and which includes source code that actually implements the routines in the module. The term module may also simply refer to an application such as a computer program designed to assist in the performance of a specific task such as word processing, accounting, inventory management, etc., or a hardware component designed to equivalently assist in the performance of a task.

The interface 3505 (e.g., a graphical user interface 3309) can serve to display results, whereupon a user 3504 may supply additional inputs or terminate a particular session. In some embodiments, operating system 3503 and GUI 3309 can be implemented in the context of a “windows” system. It can be appreciated, of course, that other types of systems are possible. For example, rather than a traditional “windows” system, other operation systems such as, for example, a real time operating system (RTOS) more commonly employed in wireless systems may also be employed with respect to operating system 3503 and interface 3505. The software application 3501 can include, for example, module(s) 3502, which can include instructions for carrying out steps, logical or arithmetic operations, and doing so on classical bits or quantum qubits, collectively called data, such as those shown and described herein.

The following description is presented with respect to embodiments of the present invention, which can be embodied in the context of, or require the use of a data-processing system such as computer system 3500, in conjunction with program module 3502, and data-processing system 3400 and network 3410 depicted in FIG. 33-35. The present invention, however, is not limited to any particular application or any particular environment. Instead, persons skilled in the art will find that the systems and methods of the present invention may be advantageously applied to a variety of system and application software including database management systems, word processors, and the like. Moreover, the present invention may be embodied on a variety of different platforms including Windows, Macintosh, UNIX, LINUX, Android, Arduino and the like. Therefore, the descriptions of the exemplary embodiments, which follow, are for purposes of illustration and not considered a limitation.

Based on the foregoing, it can be appreciated that a number of embodiments, preferred and alternative, are disclosed herein. It should be appreciated that variations of the above-disclosed and other features and functions, or alternatives thereof, may be desirably combined into many other different systems or applications. In an embodiment, a method for controlling a quantum computer comprises: moving energy from a power-clock supply to a cryostat, moving a portion of the energy through at least one switch in the cryostat, moving a portion of the energy to control of at least one analog switch in the cryostat, in order to open or close the switch, transmitting a qubit control waveform through the at least one analog switch set to closed, altering at least one qubit, moving a portion of the energy through the at least one switch that was previously set to open or closed, and moving a portion of the energy to the power-clock supply.

In an embodiment, the method further comprises measuring at least one of the qubits, analyzing the result of the measurement using a standard computer, yielding a decision, and setting at least one of the switches with the decision. In an embodiment, setting at least one of the switches comprises scheduling the setting of multiple of the at least one switches. In an embodiment, the method further comprises identifying at least one subcircuit and encoding each of the at least one subcircuits into an AL-bus word. In an embodiment, the method further comprises setting the at least one switch to the AL-bus words. In an embodiment, the method further comprises setting one switch to cause setting all the at least one analog switches to one of the AL-bus words.

In another embodiment, a method for creating a quantum computer comprises identifying a set of prime-line waveforms, turning a quantum algorithm into a subcircuit graph comprised of subcircuits of quantum operation building blocks, parameterized quantum gate operations, and decision elements, substituting a schematic diagram symbol of a bus-enabled storage unit for each subcircuit and a symbol for a parameterized quantum gate operation, connecting outputs to an address-line bus, wiring each subcircuit according to a pattern in the subcircuit graph, simulating the quantum algorithm on a classical computer based on real time measurement results, and sending decision values to a decision element in real time.

In an embodiment each of prime-line waveforms contain a time sequence of quantum operation building blocks. In an embodiment, the method further comprises fabricating a chip from the schematic diagram. In an embodiment, the method further comprises selecting prime-line waveforms from the set of prime-line waveforms to create building blocks that can be applied to a second algorithm. In an embodiment, the method further comprises executing either the quantum algorithm or the second algorithm based on decisions transmitted from the classical computer. In an embodiment, the method further comprises selecting prime-line waveforms to create building blocks that can be applied to the second algorithm. In an embodiment, the method further comprises specifying contents to be loaded into the bus-enabled storage units that can execute either the quantum algorithm, or the second algorithm. In an embodiment, the schematic diagram symbol of a bus-enabled shift register is a reversible shift register.

In another embodiment, a computing system comprises a reversible shift register, at least one power-clock generator creating a power-clock waveform, and a cable bundle between the at least one power-clock generator and the reversible shift register.

In an embodiment of the system, a waveform is predistorted to an inverse of distortion introduced by the cable bundle. In an embodiment of the system, the computing system comprises a multi-temperature hybrid computing system. In an embodiment the system further comprises a cryostat, wherein the reversible shift register is in the cryostat. In an embodiment, the system further comprises a bus interface circuit in the cryostat. In an embodiment the system further comprises an analog signal generator controlled by information from the shift register and a qubit in the cryostat.

It should be understood that various presently unforeseen or unanticipated alternatives, modifications, variations or improvements therein may be subsequently made by those skilled in the art which are also intended to be encompassed by the following claims.

What is claimed is:

1. A method for controlling a quantum computer comprising:
moving energy from a power-clock supply to a cryostat;
moving a portion of the energy through at least one switch in the cryostat;
moving a portion of the energy to control of at least one analog switch set in the cryostat, in order to open or close the at least one switch;
transmitting a qubit control waveform through the at least one analog switch set to closed, altering at least one qubit;
moving a portion of the energy through the at least one switch that was previously set to open or closed; and
moving a portion of the energy to the power-clock supply.

2. The method of claim 1 further comprising:
measuring at least one of the qubits;
analyzing a result of the measurement using a standard computer, yielding a decision;
setting at least one of the switches with the decision.

3. The method of claim 2 wherein setting at least one of the switches comprises:
scheduling the setting of multiple of the at least one switches.

4. The method of claim 2 further comprising:
identifying at least one subcircuit; and
encoding each of the at least one subcircuits into an AL-bus word.

5. The method of claim 4 further comprising:
setting the at least one switch to the AL-bus words.

6. The method of claim 5 further comprising:
setting one switch to cause setting all the at least one analog switches to one of the AL-bus words.

7. A method for creating a quantum computer comprising:
identifying a set of prime-line waveforms;
turning a quantum algorithm into a subcircuit graph comprised of subcircuits of quantum operation building blocks, parameterized quantum gate operations, and decision elements;
substituting a schematic diagram symbol of a bus-enabled storage unit for each subcircuit and a symbol for a parameterized quantum gate operation;
connecting outputs to an address-line bus;
wiring each subcircuit according to a pattern in the subcircuit graph;
simulating the quantum algorithm on a classical computer based on real time measurement results; and
sending decision values to a decision element in real time.

8. The method of claim 7 further wherein each of prime-line waveforms contain a time sequence of quantum operation building blocks.

9. The method of claim 7 further comprising:
fabricating a chip from the schematic diagram.

10. The method of claim 7 further comprising:
selecting prime-line waveforms from the set of prime-line waveforms to create building blocks that can be applied to a second algorithm.

11. The method of claim 10 further comprising:
executing either the quantum algorithm or the second algorithm based on decisions transmitted from the classical computer.

12. The method of claim 10 further comprising:
selecting prime-line waveforms to create building blocks that can be applied to the second algorithm.

13. The method of claim 12 further comprising:
specifying contents to be loaded into the bus-enabled storage units that can execute either the quantum algorithm, or the second algorithm.

14. The method of claim 7 wherein the schematic diagram symbol of a bus-enabled shift register is a reversible shift register.

15. A computing system comprising:
a reversible shift register;
at least one power-clock generator creating a power-clock waveform; and
a cable bundle between the at least one power-clock generator and the reversible shift register.

16. The computing system of claim 15 wherein a waveform is predistorted to an inverse of distortion introduced by the cable bundle.

17. The computing system of claim 15 wherein the computing system comprises a multi-temperature hybrid computing system.

18. The computing system of claim 16 further comprising:
a cryostat, wherein the reversible shift register is in the cryostat.

19. The computing system of claim 18 further comprising:
a bus interface circuit in the cryostat.

20. The computing system of claim 19 further comprising:
an analog signal generator controlled by information from the reversible shift register; and
a qubit in the cryostat.
